(19) United States
(12) Patent Application Publication
(10) Pub. No.: US 2025/0015057 A1
(43) Pub. Date: Jan. 9, 2025

(54) SEMICONDUCTOR LIGHT EMITTING DEVICE AND A DISPLAY DEVICE

(71) Applicant: LG ELECTRONICS INC., Seoul (KR)

(72) Inventors: Byoungkwon CHO, Seoul (KR); Hyeyoung YANG, Seoul (KR); Wonseok CHOI, Seoul (KR)

(73) Assignee: LG ELECTRONICS INC., Seoul (KR)

(21) Appl. No.: 18/588,902

(22) Filed: Feb. 27, 2024

(30) Foreign Application Priority Data
Jul. 3, 2023 (KR) 10-2023-0085581

(51) Int. Cl. H01L 25/075; H01L 33/46; H01L 33/62

(52) U.S. Cl. CPC H01L 25/0753; H01L 33/46; H01L 33/62; H01L 2933/0033

(57) ABSTRACT

A semiconductor light emitting device includes a light emitting layer, a first electrode on a lower side of the light emitting layer, a second electrode on an upper side of the light emitting layer, an insulating layer on a side portion of the light emitting layer and overlapping at least a portion of the first electrode and overlapping at least a portion of the second electrode and a plurality of metal layers spaced apart from each other in the insulating layer, the plurality of metal layers including a first metal layer including a reflective layer and a second metal layer including a magnetic layer.

### CROSS-REFERENCE TO RELATED APPLICATIONS

The present application claims the benefits of priority to Korean Patent Application No. 10-2023-0085581, filed on Jul. 3, 2023, all of which are incorporated herein by reference in their entireties.

### BACKGROUND OF THE DISCLOSURE

### 1. Technical Field

An embodiment relates to a semiconductor light emitting device and a display device.

### 2. Description of Related Art

A large-area display comprises a liquid crystal display (LCD), an organic light emitting diode (OLED) display, and a micro-LED display. The micro-LED display is a display that uses a micro-LED, that is, a semiconductor light emitting device with a diameter or cross-sectional area of 100 μm or less, as a display element.

Since the micro-LED display use a micro-LED (e.g., micro-LED's) as a display element, it has excellent performance in many characteristics such as contrast ratio, response speed, color gamut, viewing angle, brightness, resolution, lifespan, luminous efficiency, luminance, etc. In particular, the micro-LED display has the advantage of being able to freely adjust the size and resolution and implementing a flexible display because the screen can be separated or combined in a modular manner. However, because a large micro-LED display requires more than millions of micro-LEDs, there is a technical problem that makes it difficult to quickly and accurately transfer the micro-LEDs to the display panel.

Transfer technologies that have been recently developed include the pick and place process, laser lift-off method, or self-assembly method. Among these transfer technologies, a self-assembly method is a method in which the semiconductor light emitting device automatically moves to its assembly position within the fluid, which is advantageous for the implementation of a large-screen display device. However, there is still insufficient research on technology for manufacturing displays through self-assembly of micro-LEDs.

In the self-assembly method, numerous micro-LEDs must be accurately and quickly moved to the desired location in the fluid and accurately and quickly assembled on the substrate at the desired location. For this purpose, the self-assembly method uses magnetic and electric fields. That is, the micro-LEDs are moved to a desired location in the fluid using a magnet that generates a magnetic field, and the corresponding micro-LEDs are assembled on the substrate by the electric field. The electric field is generated by the voltage applied to the assembling wiring provided on the substrate.

In order for the micro-LED to move by the magnet, the micro-LED is provided with a magnetic layer. The magnetic layer is disposed on the lower side of the micro-LED. However, as shown in FIG. 1, when the magnetic layer is disposed on the lower side of the micro-LED (1, 2), agglomeration phenomenon occurs in which adjacent micro-LEDs 1 and 2 with magnetic layers facing each other face to face stick to each other. The agglomeration phenomenon refers to the phenomenon in which multiple micro-LEDs 1 and 2 stick to each other (e.g., are magnetically attracted/magnetically attached to one another). The smaller the size of the micro-LED and the larger the contact area of the magnetic layer of the adjacent micro-LEDs 1 and 2, the stronger the adhesion between the micro-LEDs, which is undesirable, at it leads to improper assembly or the inability to assemble the micro-LEDs 1 and 2 that are connected to one another. Numerous micro-LEDs 1 and 2 are pulled by magnets, so that the distance between micro-LEDs becomes small. Accordingly, the agglomeration phenomenon occurs in which the micro-LEDs 1 and 2 stick to each other due to the magnetic layers of each of the adjacent micro-LEDs 1 and 2.

The agglomeration phenomenon reduces assembly speed, assembly yield, lighting efficiency, among other factors. A combination of multiple micro-LEDs 1 and 2 that are attached to one another has a problem in that the assembly speed on the substrate is reduced due to a decrease in movement speed, which is a result of an increased weight. In addition, even if a combination of several connected micro-LEDs 1 and 2 is assembled in the assembly hole on the substrate, there is a problem that assembly defects occur due to separation from the assembly hole. In addition, even if the combination of several connected micro-LEDs 1 and 2 assembled in the assembly hole on the substrate does not come off (e.g., is not disassembled), there is a problem that lighting defects occur due to electrical connection defects when electrically connected in a post-process. Therefore, in order to increase the assembly speed and improve assembly yield or lighting efficiency, the most urgent solution of the embodied invention is to prevent the agglomeration phenomenon that occurs when the micro-LEDs 1 and 2 move in the fluid.

### SUMMARY OF THE DISCLOSURE

An object of the embodiment is to solve the foregoing and other problems. Another object of the embodiment is to provide a semiconductor light emitting device that can prevent agglomeration phenomenon. In addition, another purpose of the embodiment is to provide a semiconductor light emitting device that can increase the assembly speed. In addition, another purpose of the embodiment is to provide a semiconductor light emitting device that can improve assembly yield or lighting efficiency. In addition, another object of the embodiment is to provide a semiconductor light emitting device and display device that can improve brightness. The technical problem of the embodiment is not limited to those described in this section, and include those that can be grasped through the description of the invention.

According to one aspect of the embodiment to achieve the above or other object, a semiconductor light emitting device, comprising: a light emitting layer; a first electrode on a lower side of the light emitting layer; a second electrode on an upper side of the light emitting layer; an insulating layer on a side portion of the light emitting layer; and a plurality of metal layers spaced apart from each other in the insulating layer. The light emitting layer can comprise at least one or more first conductivity type semiconductor layer; an active layer on the first conductivity type semiconductor layer; and at least one or more second conductivity type semiconductor layer on the active layer.

The plurality of metal layers can comprise at least one or more first metal layer; and at least one or more second metal layer spaced outwardly from the first metal layer. The insulating layer can comprise a first insulating layer between the light emitting layer and the first metal layer; a second insulating layer between the first metal layer and the second metal layer; and a third insulating layer on an outer side surface of the second metal layer.

A portion of the third insulating layer can vertically overlap the upper side of the light emitting layer. The plurality of metal layers can comprise at least one or more third metal layer spaced outwardly from the second metal layer. The first metal layer can comprise a reflective layer, the second metal layer can comprise a magnetic layer, and the third metal layer can comprise a reflective layer. An upper side of at least one or more layer of the first metal layer, the second metal layer, and the third metal layer can coincide with an upper surface of the second electrode. An upper side of at least one or more layer of the first metal layer, the second metal layer, and the third metal layer can be located higher than an upper surface of the second conductivity type semiconductor layer. An upper side of at least one or more layer of the first metal layer, the second metal layer, and the third metal layer can be in contact with the third insulating layer.

The insulating layer can comprise a fourth insulating layer between the second metal layer and the third metal layer. An upper side of at least one or more layer of the first insulating layer, the second insulating layer, and the fourth insulating layer can be in contact with the third insulating layer. An edge area of the first electrode can be spaced apart from the first metal layer, the second metal layer, and the third metal layer through a space, and the space can be formed between lower sides of at least two or more layers of the first insulating layer, the second insulating layer, the third insulating layer, and the fourth insulating layer.

An edge area of the first electrode can be spaced apart from the first metal layer with the first insulating layer therebetween. The plurality of metal layers can comprise at least one or more fourth metal layer spaced inwardly from the first metal layer. The fourth metal layer can be disposed between the light emitting layer and the first insulating layer. The fourth metal layer can comprise an ohmic layer. An upper side of the fourth metal layer can be located lower than the active layer.

An edge area of the first electrode can be electrically connected to at least one or more layer of the first metal layer, the second metal layer, the third metal layer, and the fourth metal layer. The plurality of metal layers each can have a cylindrical structure.

According to another aspect of the embodiment, a display device, comprising: a substrate comprising a plurality of sub-pixels constituting a pixel; and a plurality of semiconductor light emitting devices in the plurality of sub-pixels, wherein the semiconductor light emitting device comprises: a light emitting layer; a first electrode on a lower side of the light emitting layer; a second electrode on an upper side of the light emitting layer; an insulating layer on a side portion of the light emitting layer; and a plurality of metal layers spaced apart from each other in the insulating layer.

The embodiment can prevent agglomeration phenomenon. As shown in FIGS. 8, 13, 15, 17, and 18, a plurality of metal layers 156-1 to 156-4 can be disposed on the side portion of the light emitting layer 150a, and one of the plurality of metal layers 156-1 to 156-4 can comprise a magnetic layer 156-2. In addition, the side surface of the light emitting layer 150a can have a round surface. The insulating layer 157 disposed on the side portion of the light emitting layer 150a can also have a round surface. Accordingly, since the semiconductor light emitting devices 150A to 150E do not stick to each other, agglomeration phenomenon can be prevented. Even if the semiconductor light emitting devices 150A to 150E are stuck by the magnetic layer 156-2 disposed on the side portion of the light emitting layer 150a, the side surface of the insulating layer 157 has a round surface, so the stuck semiconductor light emitting devices 150A to 150E can be immediately separated.

This embodiment can speed up assembly. As described above, since the semiconductor light emitting devices 150A to 150E do not stick together, the semiconductor light emitting devices 150A to 150E can be individually moved to a desired location on the substrate together with the magnet. Therefore, when agglomeration phenomenon of the semiconductor light emitting devices 150A to 150E occurs, the problem of slowing down the movement speed due to the weight of the clumped together semiconductor light emitting devices 150A to 150E formed by agglomeration or slowing down the assembly speed due to the magnet not moving quickly or not moving at all can be solved.

The embodiment can improve assembly yield or lighting yield. As shown in FIGS. 19 to 22, only one semiconductor light emitting device 150A to 150E can be assembled in the assembly hole 340H on the substrate 310. Accordingly, since the semiconductor light emitting devices 150A to 150E are assembled in all of the assembly holes 340H provided on the substrate 310 (e.g., each of the semiconductor light emitting devices 150A to 150E are assembled into a respective one of the assembly holes 340H), assembly yield can be improved. In addition, since one semiconductor light emitting device 150A to 150E is assembled per assembly hole 340H, electrical connection defects such as disconnection do not occur during electrical connection in the post-process, and lighting efficiency can be improved.

The embodiment can improve luminance. A reflective layer 154-1 can be included in the first electrode 154 disposed on the lower side of the light emitting layer 150a, and one of a plurality of metal layers 156-1 to 156-4 disposed on the side portion of the light emitting layer 150a can comprise a reflective layer 156-1. Accordingly, the light generated inside the light emitting layer 150a can be more easily extracted to the outside, thereby improving luminance.

A further scope of applicability of the embodiment will become apparent from the detailed description that follows. However, since various changes and modifications within the spirit and scope of the embodiment can be clearly understood by those skilled in the art, it should be understood that the detailed description and specific embodiment, such as preferred embodiment, are given by way of example only.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 illustrate the peeling of reflective metal from a micro-LED.

FIG. 2 illustrates a living room of a house in which a display device according to an embodiment is disposed.

FIG. 3 is a block diagram schematically illustrating a display device according to an embodiment.

FIG. 4 is a circuit diagram showing an example of a pixel of FIG. 3.

FIG. 5 is an enlarged view of a first panel region in the display device of FIG. 3.

FIG. 6 is an enlarged view of the area A2 of FIG. 5.

FIG. 7 is a view showing an example in which a light emitting device according to an embodiment is assembled to a substrate by a self-assembly method.

FIG. 8 is a cross-sectional view illustrating a semiconductor light emitting device according to a first embodiment.

FIG. 9 is a bottom view illustrating the semiconductor light emitting device according to the first embodiment after the first electrode has been removed.

FIG. 10 shows adjacent semiconductor light emitting devices sticking together in each of a comparative example and the embodiment.

FIG. 11 shows the magnetic field of a magnet being applied to a cylindrical structure of the second metal layer.

(a) to (d) of FIG. 12A and (e) to (g) of FIG. 12B show the manufacturing process of the semiconductor light emitting device according to the first embodiment.

FIG. 13 is a cross-sectional view illustrating a semiconductor light emitting device according to a second embodiment.

FIG. 14 is a bottom view illustrating the semiconductor light emitting device according to the second embodiment after the first electrode has been removed.

FIG. 15 is a cross-sectional view illustrating a semiconductor light emitting device according to a third embodiment.

FIG. 16 illustrates a manufacturing process of a semiconductor light emitting device according to the third embodiment.

FIG. 17 is a cross-sectional view illustrating a semiconductor light emitting device according to a fourth embodiment.

FIG. 18 is a cross-sectional view illustrating a semiconductor light emitting device according to a fifth embodiment.

FIG. 19 is a cross-sectional view illustrating a display device according to a first embodiment.

FIG. 20 is a cross-sectional view illustrating a backplane substrate according to the first embodiment.

FIG. 21 is a cross-sectional view illustrating a display device according to a second embodiment.

FIG. 22 is a cross-sectional view illustrating a backplane substrate according to the second embodiment.

FIG. 23 shows the luminance of a semiconductor light emitting device in a display device according to a comparative example and the embodiment.

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### DETAILED DESCRIPTION OF THE EMBODIMENTS

The present invention will now be described with reference to the accompanying drawings, wherein the same reference numerals have been used to identify the same or similar elements throughout the several views.

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of case of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

The display device described in this specification can comprise TV, signage, mobile terminal such as handheld phone and smart phone, display for computer, such as a laptop and a desktop, head-up display (HUD) for automobiles, backlight unit for display, XR (Extend Reality) such as AR, VR, MR (mixed reality), etc. However, the configuration according to the embodiment described in this specification can be applied to a display-capable device even if it is a new product type to be developed in the future.

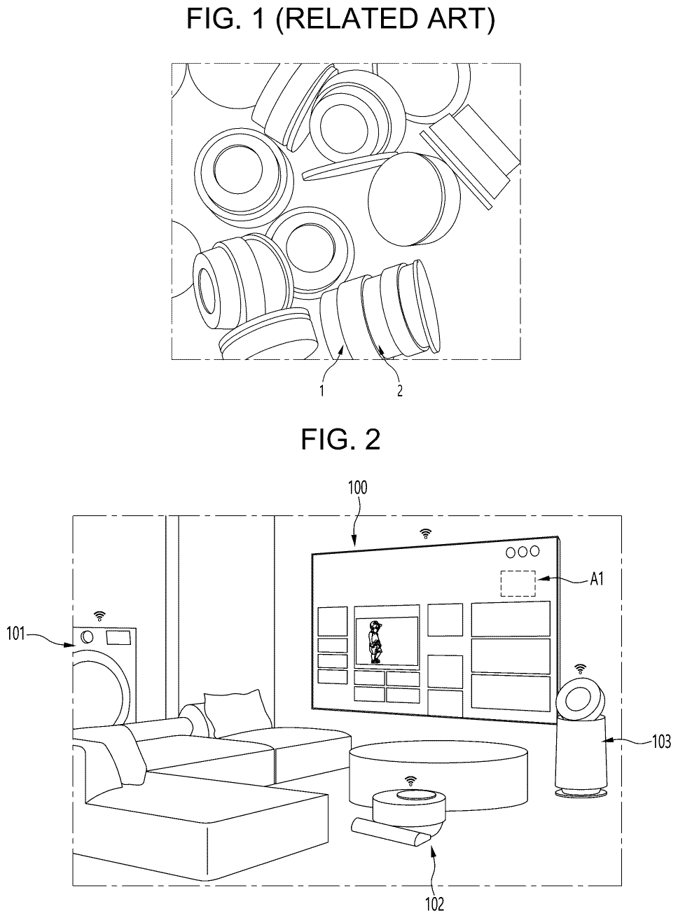

FIG. 2 illustrates a living room of a house in which a display device according to an embodiment is disposed. Referring to FIG. 2, the display device 100 of the embodiment can display the status of various electronic products such as a washing machine 101, a robot cleaner 102, and an air purifier 103, communicate with each electronic product based on IoT and control each electronic product based on user's setting data.

The display device 100 according to the embodiment can include a flexible display manufactured on a thin and flexible substrate. The flexible display can be bent or rolled like paper while maintaining the characteristics of an existing flat panel display.

In the flexible display, visual information can be implemented by independently controlling light emission of a unit pixel arranged in a matrix form. The unit pixel means a minimum unit for implementing one color. The unit pixel of the flexible display can be implemented by a light emitting device. In the embodiment, the light emitting device can be Micro-LED or Nano-LED (e.g., electroluminescent quantum dots (EL-QD), but is not limited thereto.

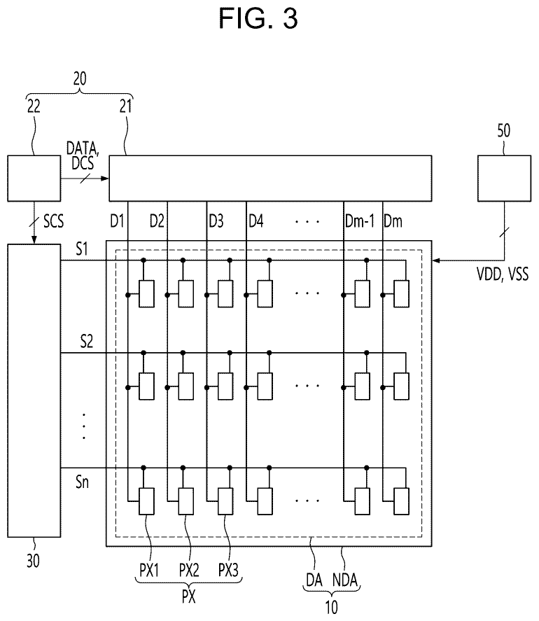

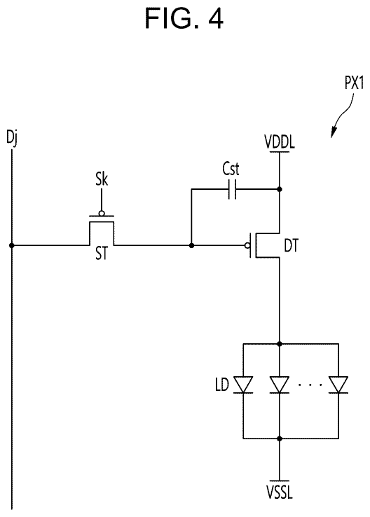

FIG. 3 is a block diagram schematically illustrating a display device according to an embodiment. FIG. 4 is a circuit diagram showing an example of a pixel of FIG. 3. Referring to FIG. 3 and FIG. 4, a display device according to an embodiment can comprise a display panel 10, a driving circuit 20, a scan driving circuit 30 and a power supply circuit 50.

The display device 100 of the embodiment can drive a light emitting device in an active matrix (AM) scheme or a passive matrix (PM) scheme. The driving circuit 20 can comprise a data driving circuit 21 and a timing controller 22. The display panel 10 can have a rectangular shape, but is not limited thereto. That is, the display panel 10 can be formed in a circular or elliptical shape. At least one side of the display panel 10 can be formed to be bent with a predetermined curvature. The display panel can comprise a display area DA. The display area DA is an area where pixels PX are formed to display an image. The display panel can comprise a non-display area (NDA). The non-display area DNA can be an area excluding the display area DA.

As an example, the display area DA and the non-display area NDA can be defined on the same surface. For example, the non-display area DNA can surround the display area DA on the same side as the display area DA, but is not limited thereto. As another example, the display area DA and the non-display area NDA can be defined on different surfaces. For example, the display area DA can be defined on an upper surface of the substrate, and the non-display area NDA can be defined on a lower surface of the substrate. For example, the non-display area NDA can be defined on the entire or partial area of the lower surface of the substrate.

For example, although it is shown in the drawing as being divided into a display area DA and a non-display area NDA, it may not be divided into a display area DA and a non-display area NDA. That is, only the display area DA can exist on the upper surface of the substrate, and the non-display area NDA may not exist. In other words, the entire upper surface of the substrate can be the display area DA where images are displayed, and the bezel area that is the non-display area NDA may not exist.

The display panel 10 can comprise data lines (D1 to Dm, where m is an integer greater than or equal to 2), scan lines (S1 to Sn, where n is an integer greater than or equal to 2) crossing the data lines (D1 to Dm), a high potential voltage line VDDL supplied with a high potential voltage, a low potential voltage line VSSL supplied with a low potential voltage, and pixels PX connected to the data lines D1 to Dm and the scan lines S1 to Sn, as shown in FIG. 4.

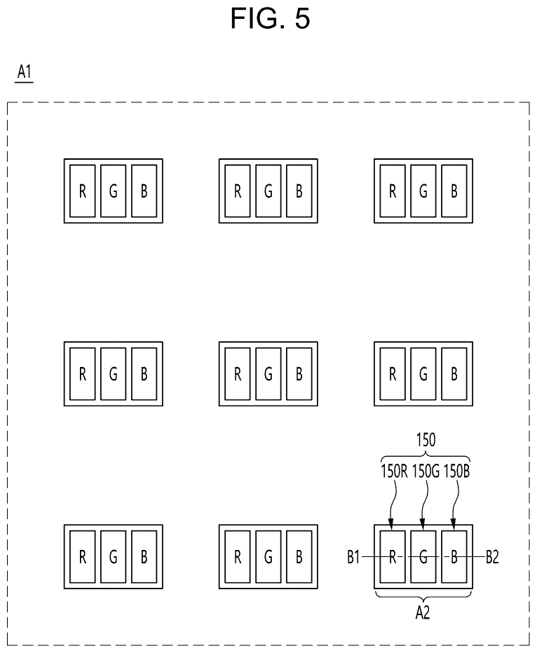

Each of the pixels PX can comprise a first sub-pixel PX1, a second sub-pixel PX2, and a third sub-pixel PX3. The first sub-pixel PX1 can emit a first color light with a first main wavelength, the second sub-pixel PX2 can emit of a second color light with a second main wavelength, and the third sub-pixel PX3 can emit a third color light with a third main wavelength. That is, each of the first sub-pixel PX1, the second sub-pixel PX2 and the third sub-pixel PX3 can emit different colors. The first color light can be red light, the second color light can be green light, and the third color light can be blue light, but are not limited thereto. In addition, in FIG. 5, it is illustrated that each of the pixels PX comprise three sub-pixels, but are not limited thereto. That is, each of the pixels PX can comprise four or more sub-pixels.

Each of the first sub-pixel PX1, the second sub-pixel PX2, and the third sub-pixel PX3 can be connected to at least one of the data lines D1 to Dm, at least one of the scan lines S1 to Sn, and a high potential voltage line VDDL. As shown in FIG. 4, the first sub-pixel PX1 can include light emitting devices LDs, a plurality of transistors for supplying current to the light emitting devices LDs, and at least one capacitor Cst.

Each of the first sub-pixel PX1, the second sub-pixel PX2, and the third sub-pixel PX3 can include only one light emitting device LD and at least one capacitor Cst. Each of the light emitting devices LD can be a semiconductor light emitting diode comprising a first electrode, a plurality of conductivity type semiconductor layers, and a second electrode. Here, the first electrode can be an anode electrode, and the second electrode can be a cathode electrode, but is not limited thereto. The light emitting device LD can be one of a lateral type light emitting device, a flip-chip type light emitting device, and a vertical type light emitting device.

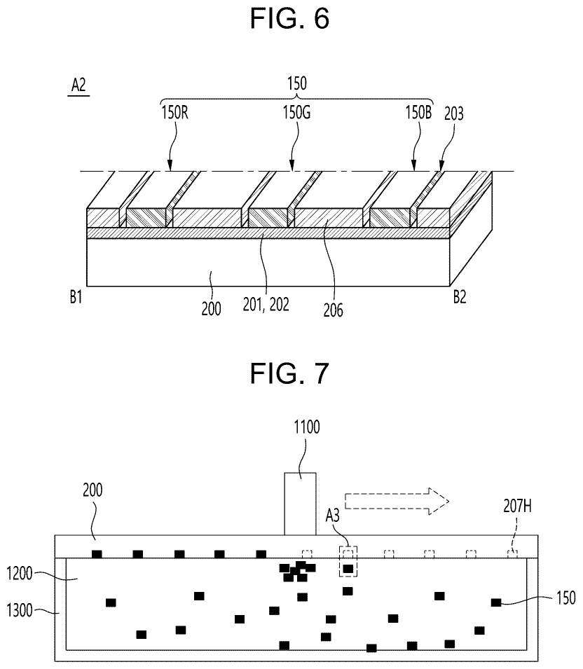

The plurality of transistors can include a driving transistor DT supplying current to the light emitting devices LD and a scan transistor ST supplying a data voltage to a gate electrode of the driving transistor DT, as shown in FIG. 6. The driving transistor DT has a gate electrode connected to the source electrode of the scan transistor ST, a source electrode connected to the high potential voltage line VDDL to which a high potential voltage is applied, and a drain electrode connected to the first electrodes of the light emitting devices LD. The scan transistor ST has a gate electrode connected to the scan line (Sk, k is an integer that satisfies 1≤k≤n), a source electrode connected to the gate electrode of the driving transistor DT, and a drain electrode connected to the data lines (Dj, j an integer that satisfies 1≤j≤m).

The capacitor Cst is formed between the gate electrode and the source electrode of the driving transistor DT. The storage capacitor Cst stores a difference voltage between a gate voltage and a source voltage of the driving transistor DT.

The driving transistor DT and the scan transistor ST can be formed of a thin film transistor. In addition, in FIG. 4, the driving transistor DT and the scan transistor ST have been mainly described as being formed of P-type MOSFETs (Metal Oxide Semiconductor Field Effect Transistors), but are not limited thereto. The driving transistor DT and the scan transistor ST can be formed of N-type MOSFETs. In this instance, positions of the source electrode and the drain electrode of each of the driving transistor DT and the scan transistor ST can be changed.

In addition, in FIG. 4, it is illustrated that each of the first sub-pixel PX1, the second sub-pixel PX2, and the third sub-pixel PX3 includes 2TIC (2 Transistor-1 capacitor) having one driving transistor DT, one scan transistor ST, and one capacitor Cst, but is not limited thereto. Each of the first sub-pixel PX1, the second sub-pixel PX2, and the third sub-pixel PX3 can include a plurality of scan transistors ST and a plurality of capacitors Cst.

Since the second sub-pixel PX2 and the third sub-pixel PX3 can be expressed with substantially the same circuit diagram as the first sub-pixel PX1, detailed descriptions will be omitted.

The driving circuit 20 outputs signals and voltages for driving the display panel 10. The driving circuit 20 can include a data driving circuit 21 and a timing controller 22. The data driving circuit 21 receives digital video data DATA and a source control signal DCS from the timing controller 22. The data driving circuit 21 converts the digital video data DATA into analog data voltages according to the source control signal DCS and supplies them to the data lines D1 to Dm of the display panel 10.

The timing controller 22 receives digital video data DATA and timing signals from a host system. The timing signals can include a vertical synchronization signal, a horizontal synchronization signal, a data enable signal, and a dot clock. The host system can be an application processor of a smart phone or tablet PC, a system on chip of a monitor or TV, or the like.

The timing controller 22 generates control signals for controlling operation timings of the data driving circuit 21 and the scan driving circuit 30. The control signals can include a source control signal DCS for controlling the operation timing of the data driving circuit 21 and a scan control signal SCS for controlling the operation timing of the scan driving circuit 30.

The driving circuit 20 can be disposed in the non-display area NDA provided on one side of the display panel 10. The driving circuit 20 can be formed of an integrated circuit (IC) and mounted on the display panel 10 using a chip on glass (COG) scheme, a chip on plastic (COP) scheme, or an ultrasonic bonding scheme, but is not limited thereto. For example, the driving circuit 20 can be mounted on a circuit board instead of the display panel 10.

The data driving circuit 21 can be mounted on the display panel 10 using a chip on glass (COG) scheme, a chip on plastic (COP) scheme, or an ultrasonic bonding scheme, and the timing controller 22 can be mounted on a circuit board, but is not limited thereto.

The scan driving circuit 30 receives the scan control signal SCS from the timing controller 22. The scan driving circuit 30 generates scan signals according to the scan control signal SCS and supplies them to the scan lines S1 to Sn of the display panel 10. The scan driving circuit 30 can include a plurality of transistors and be formed in the non-display area NDA of the display panel 10. Alternatively, the scan driving circuit 30 can be formed as an integrated circuit, and in this instance, it can be mounted on a gate flexible film attached to the other side of the display panel 10.

The power supply circuit 50 can generate voltages necessary for driving the display panel 10 from the main power supplied from the system board and supply the voltages to the display panel 10. For example, the power supply circuit 50 generates a high potential voltage VDD and a low potential voltage VSS for driving the light emitting devices LD of the display panel 10 from the main power supply to supply them to the high potential voltage line VDDL and the low potential voltage line VSSL. Also, the power supply circuit 50 can generate and supply driving voltages for driving the driving circuit 20 and the scan driving circuit 30 from the main power.

FIG. 5 is an enlarged view of a first panel region in the display device of FIG. 3.

Referring to FIG. 5, a display device 100 of the embodiment can be manufactured by mechanically and electrically connecting a plurality of panel regions such as the first panel region A1 by tiling. The first panel region A1 can include a plurality of light emitting devices 150 disposed for each unit pixel (PX in FIG. 3).

FIG. 6 is an enlarged view of the area A2 of FIG. 5. Referring to FIG. 6, a display device 100 according to an embodiment can comprise a substrate 200, assembling wirings 201 and 202, an insulating layer 206, and a plurality of semiconductor light emitting devices 150. More components can be included in the display device 100.

The assembling wiring can comprise a first assembling wiring 201 and a second assembling wiring 202 spaced apart from each other. The first assembling wiring 201 and the second assembling wiring 202 can be provided to generate a dielectrophoretic (DEP) force so that the semiconductor light emitting device 150 can be assembled. For example, the semiconductor light emitting device 150 can be one of a lateral type semiconductor light emitting device, a flip-chip type semiconductor light emitting device, and a vertical type semiconductor light emitting device but is not limited thereto.

The semiconductor light emitting device 150 can comprise a red semiconductor light emitting device 150R, a green semiconductor light emitting device 150G, and a blue semiconductor light emitting device 150B to form a sub-pixel, but is not limited thereto. In other words, red and green can be implemented by providing a red phosphor and a green phosphor.

The substrate 200 can be a support member for supporting components disposed on the substrate 200 or a protective member for protecting the components.

The substrate 200 can be a rigid substrate or a flexible substrate (e.g., substantially flexible substrate). The substrate 200 can be formed of sapphire, glass, silicon or polyimide. In addition, the substrate 200 can comprise a flexible material such as polyethylene naphthalate (PEN) or polyethylene terephthalate (PET). In addition, the substrate 200 can be a transparent material, but is not limited thereto. The substrate 200 can function as a support substrate in a display panel, and can also function as a substrate for assembly when self-assembling a light emitting device.

The substrate 200 can be a backplane provided with circuits in the sub-pixels PX1, PX2, and PX3 shown in FIGS. 3 and 4, for example, transistors ST and DT, a capacitor Cst, signal wirings, etc., but not limited thereto. The insulating layer 206 can comprise an insulating and flexible organic material such as polyimide, poly aluminum chloride (PAC), PEN, PET, polymer, etc. The insulating layer 206 can comprise an inorganic material, such as silicon oxide (SiO2) or silicon nitride series (SiNx). The insulating layer 206 can be integrally formed with the substrate 200 to form one substrate.

The insulating layer 206 can be a conductive adhesive layer having adhesiveness and conductivity. The conductive adhesive layer can have ductility to enable a flexible function of the display device. For example, the insulating layer 206 can be an anisotropic conductive film (ACF). For example, the insulating layer 206 can a conductive adhesive layer, such as an anisotropic conductive medium or a solution containing conductive particles. The conductive adhesive layer can be a layer that is electrically conductive in a direction perpendicular to the thickness but electrically insulating in a direction horizontal to the thickness.

The insulating layer 206 can comprise an assembly hole 203 into which the semiconductor light emitting device 150 is inserted. Therefore, during self-assembly, the semiconductor light emitting device 150 can be easily inserted into the assembly hole 203 of the insulating layer 206. The assembly hole 203 can be called an insertion hole, a fixing hole, an alignment hole, or the like.

The assembly hole 203 can be called a hole, dent, groove, recess, pocket, etc. The assembly hole 203 can be different according to the shape of the semiconductor light emitting device 150. For example, each of a red semiconductor light emitting device, a green semiconductor light emitting device, and a blue semiconductor light emitting device can have a different shape, and the assembly hole 203 having a shape corresponding to the shape of each of these semiconductor light emitting devices can be provided. For example, the assembly hole 203 can comprise a first assembly hole for assembling the red semiconductor light emitting device, a second assembly hole for assembling the green semiconductor light emitting device, and a third assembly hole for assembling the blue semiconductor light emitting device. For example, the red semiconductor light emitting device has a circular shape, the green semiconductor light emitting device has a first elliptical shape having a first minor axis and a second major axis, and the bluc semiconductor light emitting device has a second elliptical shape having a second minor axis and a second major axis, but is not limited thereto. The second major axis of the elliptical shape of the blue semiconductor light emitting device can be larger than the second major axis of the elliptical shape of the green semiconductor light emitting device, and the second minor axis of the elliptical shape of the blue semiconductor light emitting device can be smaller than the first minor axis of the elliptical shape of the green semiconductor light emitting device.

A method of mounting the semiconductor light emitting device 150 on the substrate 200 can comprise, for example, a self-assembly method (FIG. 7) and a transfer method. FIG. 7 illustrates an example in which a light emitting device according to an embodiment is assembled to a substrate by a self-assembly method. An example of assembling a semiconductor light emitting device according to the embodiment to a display panel by a self-assembly method using an electromagnetic field will be described based on FIG. 7.

The assembling substrate 200 described below can also function as a panel substrate in the display device after assembling the light emitting device, but the embodiment is not limited thereto. Referring to FIG. 7, the semiconductor light emitting device 150 can be put into a chamber 1300 filled with a fluid 1200, and the semiconductor light emitting device 150 can move to the assembling substrate 200 by the magnetic field generated from an assembly device 1100. The light emitting device 150 adjacent to the assembly hole 207H of the assembling substrate 200 can be assembled into the assembly hole 207H by a DEP force generated by the electric field of the assembling wirings. The fluid 1200 can be water such as a deionized water, but is not limited thereto. The chamber 1300 can also be called a water bath, container, vessel, etc.

After the semiconductor light emitting device 150 is put into the chamber 1300, the assembling substrate 200 can be disposed on the chamber 1300. According to the embodiment, the assembling substrate 200 can be put into the chamber 1300.

An electric field can form an electric field in response to the application of an AC voltage, and the semiconductor light emitting device 150 injected into the assembly hole 207H can be fixed by the DEP force caused by the electric field. The distance between the first assembling wiring 201 and the second assembling wiring 202 can be smaller than the width of the semiconductor light emitting device 150 or the width of the assembly hole 207H. Accordingly, the assembly position of the semiconductor light emitting device 150 using the electric field can be more accurately fixed.

An insulating layer can be formed on the first assembling wiring 201 and the second assembling wiring 202. Accordingly, the first assembling wiring 201 and the second assembling wiring 202 are protected from the fluid 1200, and leakage of current flowing through the first assembling wiring 201 and the second assembling wiring 202 can be prevented. For example, the insulating layer can be formed of a single layer or multiple layers of an inorganic insulator, such as silica or alumina, an organic insulator and the like. The insulating layer can have a minimum thickness to prevent damage to the first assembling wiring 201 and the second assembling wiring 202 when the semiconductor light emitting device 150 is assembled. The insulating layer can have a maximum thickness for stably assembling the semiconductor light emitting device 150.

A barrier rib can be formed on an upper side of the insulating layer. The barrier rib can be the insulating layer 206 shown in FIG. 5, but is not limited thereto. A portion of the barrier rib can be positioned on an upper side of the first assembling wiring 201 and the second assembling wiring 202, and the remaining portion can be positioned on an upper side of the assembling substrate 200.

When the assembling substrate 200 is manufactured, a part of the barrier ribs formed on an upper side of the insulating layer can be removed. Thus, the assembly hole 207H through which each of the semiconductor light emitting devices 150 is coupled and assembled to the assembling substrate 200 can be formed.

The assembly hole 207H to which the semiconductor light emitting devices 150 are coupled is formed in the assembling substrate 200, and a surface on which the assembly hole 207H is formed can contact the fluid 1200. The assembly hole 207H can guide an accurate assembly position of the semiconductor light emitting device 150.

The assembly hole 207H can have a shape and size corresponding to the shape of the semiconductor light emitting device 150 to be assembled at a corresponding position. Accordingly, it is possible to prevent assembly of other semiconductor light emitting devices or assembly of a plurality of semiconductor light emitting devices into the assembly hole 207H.

Referring back to FIG. 7, after the assembling substrate 200 is disposed in the chamber, the assembly device 1100 applying a magnetic field can move along the assembling substrate 200. The assembly device 1100 can be a permanent magnet or an electromagnet.

The assembly device 1100 can move while in contact with the assembling substrate 200 in order to maximize a region of influence of the magnetic field into the fluid 1200. According to the embodiment, the assembly device 1100 can comprise a plurality of magnetic bodies or can comprise a magnetic body having a size corresponding to that of the assembling substrate 200. In this instance, the moving distance of the assembling device 1100 can be limited within a predetermined range.

The semiconductor light emitting device 150 in the chamber 1300 can move toward the assembly device 1100 and the assembling substrate 200 by the magnetic field generated by the assembly device 1100.

The semiconductor light emitting device 150 can enter into the assembly hole 207H and be fixed in the assembly hole 207H by a DEP force while moving toward the assembly device 1100. The DEP force can be formed by an electric field between the assembling wirings 201 and 202 (see FIG. 6). Since the self-assembly method using the above-described electric/magnetic field can drastically reduce the time required to assemble each of the semiconductor light emitting devices to the substrate, a large-area high-pixel display can be implemented more quickly and economically.

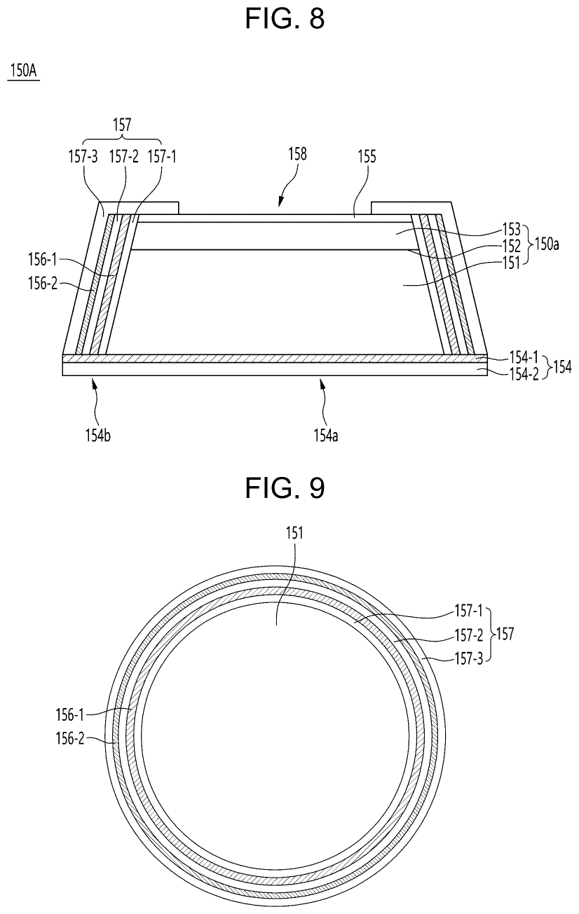

Hereinafter, various embodiments for solving the above-described problem will be described with reference to FIGS. 8 to 23. Descriptions omitted below can be easily understood from the description given above in relation to FIGS. 2 to 7 and the corresponding drawings.

The semiconductor light emitting device described below can have a size of micrometer or less. In addition, the semiconductor light emitting device described below can be a vertical semiconductor light emitting device in which current flows vertically, but is not limited thereto.

[First embodiment] FIG. 8 is a cross-sectional view illustrating a semiconductor light emitting device according to a first embodiment. FIG. 9 is a bottom view illustrating the semiconductor light emitting device according to the first embodiment after the first electrode has been removed.

Referring to FIG. 8, the semiconductor light emitting device 150A according to the first embodiment can comprise a light emitting layer 150A, a first electrode 154, a second electrode 155, an insulating layer 157, and a plurality of metal layers 156-1 and 156-2. The semiconductor light emitting device 150A according to the first embodiment can comprise more components than them above. Each side surface of the light emitting layer 150a, the insulating layer 157, and each of the metal layers 156-1 and 156-2 can have a round surface with a predetermined curvature. The curvature of each side surface of the light emitting layer 150a, the insulating layer 157, and the metal layers 156-1 and 156-2 can be the same, but is not limited thereto.

The light emitting layer 150A can emit light of a specific color. The specific color light can be determined by the semiconductor material of the light emitting layer 150A. The specific color light can be, for example, red light, green light, or blue light.

The light emitting layer 150A can comprise a plurality of semiconductor layers. For example, the light emitting layer 150A can comprise at least one first conductivity type semiconductor layer 151, an active layer 152, and at least one second conductivity type semiconductor layer 153. The active layer 152 can be disposed on the first conductivity type semiconductor layer 151 and the second conductivity type semiconductor layer 153 can be disposed on the active layer 152. The first conductivity type semiconductor layer 151 can comprise an n-type dopant, and the second conductivity type semiconductor layer 153 can comprise a p-type dopant, but is not limited thereto.

The first electrode 154 can be disposed below the light emitting layer 150A. The first electrode 154 can be disposed on the lower side of the light emitting layer 150A. The first electrode 154 can be disposed on the lower side of the first conductivity type semiconductor layer 151.

The first electrode 154 can be a cathode electrode and can have a multilayer structure comprising a plurality of layers. For example, the first electrode 154 can comprise a reflective layer 154-1, an electrode layer 154-2, etc.

The reflective layer 154-1 can be disposed below the light emitting layer 150A. The reflective layer 154-1 can be disposed on the lower side of the light emitting layer 150A. The reflective layer 154-1 can be disposed on the lower side of the first conductivity type semiconductor layer 151. The reflective layer 154-1 can be a metal with excellent (e.g., high) reflectivity and can comprise aluminum (Al), silver (Ag), a gold (Ag)-palladium (Pd)-copper (Cu) alloy (APC), etc.

An ohmic contact layer can be disposed below the first conductivity type semiconductor layer 151. In this instance, the reflective layer 154-1 can contact the first conductivity type semiconductor layer 151 through the ohmic contact layer, but is not limited thereto. The ohmic contact layer can be disposed on a top (e.g., exposed) surface of the reflective layer 154-1.

The electrode layer 154-2 can be made of a metal with excellent electrical conductivity. The electrode layer 154-2 can comprise solder metal. The solder metal can comprise tin (Sn)-lead (Pb), Sn—Pb-bismuth (Bi), Sn-gold (Au), Sn—Sb, Pb—Ag, etc. A barrier rib 340 can be provided onto a first insulating layer 330 to guide installation of the light emitting device 150A, which is to be described in more detail.

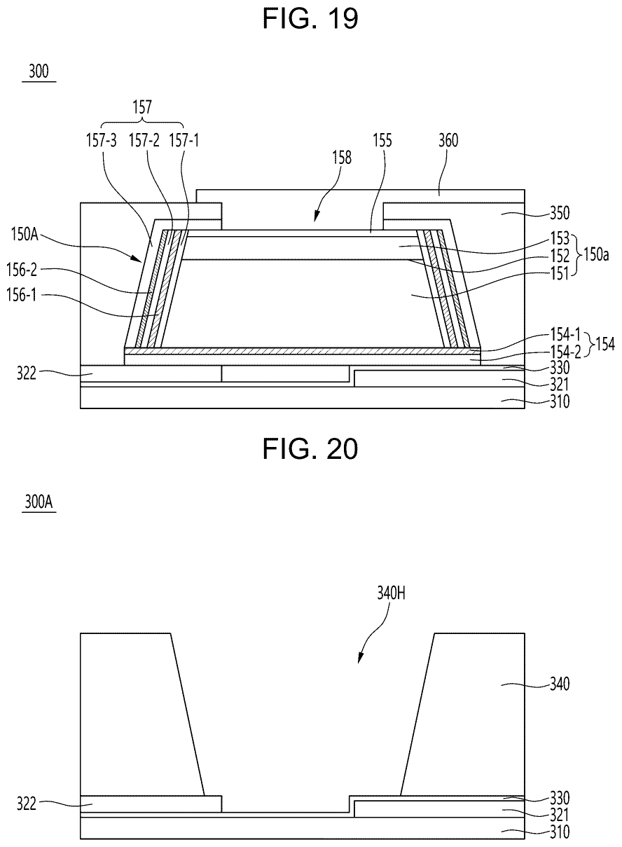

After the semiconductor light emitting device 150A according to the first embodiment is assembled in the assembly hole 340H of the backplane substrate (300A in FIG. 20), a thermal compression process can be performed to directly electrically connect the first electrode 154 to be the second assembling wiring 322. Thereafter, the barrier rib 340 can be removed and the second insulating layer 157-2 and the electrode wiring 360 can be formed, so that the display device (300 in FIG. 19) according to the first embodiment can be manufactured.

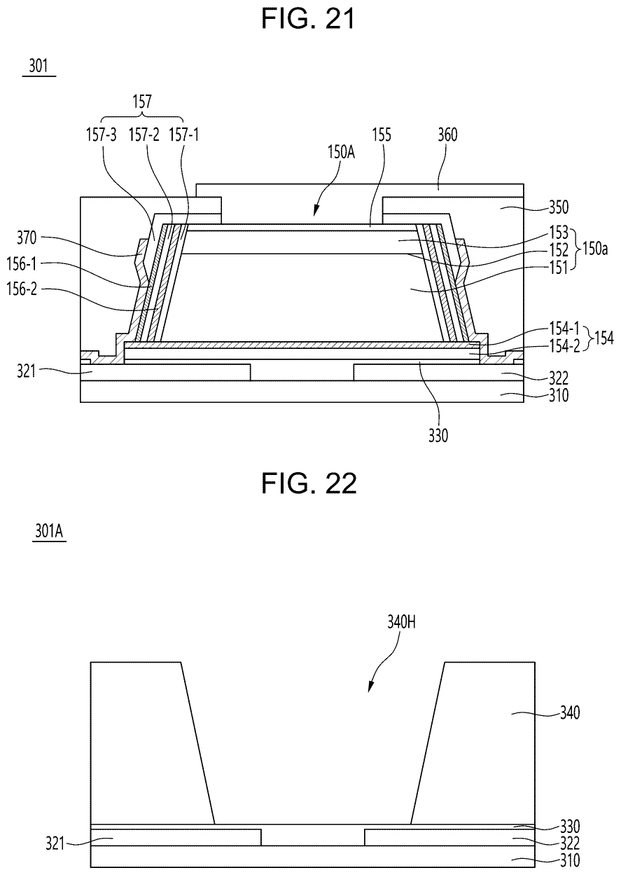

The electrode layer 154-2 can be made of a metal with excellent electrical conductivity other than solder metal. In this instance, the semiconductor light emitting device 150A according to the first embodiment can be assembled in the assembly hole 340H of the backplane substrate (301A in FIG. 22) and the barrier rib 340 can be removed such that the second insulating layer 157-2 and the electrode wiring 360 can be formed. Thus, the display device (301 in FIG. 21) according to the second embodiment can be manufactured. The display device 301 according to the second embodiment can solve problems that occur during the thermal compression process when manufacturing the semiconductor light emitting device 150A according to the first embodiment.

The second electrode 155 can be disposed on the light emitting layer 150A. The second electrode 155 can be an anode electrode and can have a multilayer structure comprising one layer or multiple layers. The second electrode 155 can be disposed on the upper side of the second conductivity type semiconductor layer 153 of the light emitting layer 150A. The second electrode 155 can be in contact with the upper surface of the second conductivity type semiconductor layer 153 of the light emitting layer 150A, but is not limited thereto. The size of the second electrode 155 can be smaller than the size of the light emitting layer 150A. The second electrode 155 can be a transparent conductor so that the light of the active layer 152 can be emitted forward, and can comprise ITO, IZO, etc.

The plurality of metal layers 156-1 and 156-2 can be disposed to be spaced apart from each other. That is, the plurality of metal layers 156-1 and 156-2 may not be in contact with each other.

The plurality of metal layers 156-1 and 156-2 can comprise at least one or more first metal layer 156-1 and at least one or more second metal layer 156-2.

The first metal layer 156-1 can be provided to increase reflection efficiency. That is, the first metal layer 156-1 can comprise a reflective layer. For example, the first metal layer 156-1 can be a metal with excellent reflectivity and can comprise Al, Ag, APC (Ag—Pd—Cu alloy), etc.

The first metal layer 156-1 can be disposed adjacent to the side portion (e.g., lateral portion) of the light emitting layer 150a. The first metal layer 156-1 can be disposed closer to the side portion of the light emitting layer 150a than the second metal layer 156-2. The first metal layer 156-1 can be disposed along the perimeter of the side portion of the light emitting layer 150a. The upper side of the first metal layer 156-1 can coincide with the upper surface of the second electrode 155. That is, the upper side of the first metal layer 156-1 and the upper surface of the second electrode 155 can be located on the same horizontal line. The upper side of the first metal layer 156-1 can be positioned higher than the upper surface of the second conductivity type semiconductor layer 153. Accordingly, light traveling laterally in the active layer 152 can be reflected forward by the first metal layer 156-1, thereby improving light output efficiency and increasing luminance.

The second metal layer 156-2 can serve to assist the movement of the semiconductor light emitting device 150A during self-assembly. The second metal layer 156-2 can comprise a magnetic layer. For example, the second metal layer 156-2 can be a material with excellent magnetization ability and can comprise Ni, Co, Fe, etc. The intensity of magnetization of the magnetic layer can be determined by the area or thickness of the magnetic layer.

The second metal layer 156-2 can be disposed to be spaced outwardly from the first metal layer 156-1. The second metal layer 156-2 can be disposed along the perimeter of the side portion of the light emitting layer 150a. The second metal layer 156-2 can be disposed along the perimeter of the side portion of the first metal layer 156-1.

The upper side of the second metal layer 156-2 can coincide with the upper surface of the second electrode 155. That is, the upper side of the second metal layer 156-2 and the upper surface of the second electrode 155 can be located on the same horizontal line. The upper side of the second metal layer 156-2 can be positioned higher than the upper surface of the second conductivity type semiconductor layer 153. Accordingly, the area of the second metal layer 156-2 can be maximized, thereby increasing the magnetization force and increasing the movement speed of the semiconductor light emitting device 150A during self-assembly. Thus, the assembly speed can be increased.

The upper side of the second metal layer 156-2 can coincide with the upper side of the first metal layer 156-1. That is, the upper side of the first metal layer 156-1 and the upper side of the second metal layer 156-2 can be located on the same horizontal line. As will be explained later, the first metal layer 156-1 and the second metal layer 156-2 can be formed using the same photosensitive film such that the manufacturing process can be simplified and the manufacturing process time can be shortened.

At least one or more of the plurality of metal layers 156-1 and 156-2 can be in contact with the first electrode 154. As an example, the first metal layer 156-1 can be in contact with the first electrode 154. The first metal layer 156-1 can be in contact with the reflective layer 154-1 of the first electrode 154. The lower side of the first metal layer 156-1 can be in contact with the upper surface of the reflective layer 154-1 of the first electrode 154. Since the first metal layer 156-1 comprises a reflective layer and the first metal layer 156-1 and the reflective layer 154-1 of the first electrode 154 are in contact with each other, light generated inside the light emitting layer 150a may not be transmitted between the first metal layer 156-1 and the reflective layer 154-1 of the first electrode 154. This arrangement can maximize reflection efficiency and increase luminance.

As another example, the second metal layer 156-2 can be in contact with the first electrode 154. The second metal layer 156-2 can be in contact with the electrode layer 154-2 of the first electrode 154. The lower side of the second metal layer 156-2 can be in contact with the upper surface of the reflective layer 154-1 of the first electrode 154. The insulating layer 157 can be in contact with the first electrode 154. At least one or more layer of the first insulating layer 157-1, the second insulating layer 157-2, and the third insulating layer 157-3 can be in contact with the first electrode 154.

As an example, the first insulating layer 157-1 can be in contact with the reflective layer 154-1 of the first electrode 154. The lower side of the first insulating layer 157-1 can be in contact with the upper surface of the reflective layer 154-1 of the first electrode 154. As another example, the second insulating layer 157-2 can be in contact with the reflective layer 154-1 of the first electrode 154. The lower side of the second insulating layer 157-2 can be in contact with the upper surface of the reflective layer 154-1 of the first electrode 154. As another example, the third insulating layer 157-3 can be in contact with the reflective layer 154-1 of the first electrode 154. The lower side of the third insulating layer 157-3 can be in contact with the upper surface of the reflective layer 154-1 of the first electrode 154.

The first metal layer 156-1 and/or the second metal layer 156-2 can have poor bonding performance with the first electrode 154. Therefore, since at least one or more of not only the first metal layer 156-1 and the second metal layer 156-2, but also the first insulating layer 157-1, the second insulating layer 157-2, and the third insulating layer 157-3 can be in contact with the first electrode 154, the bonding performance between the first electrode 154 and the plurality of metal layers 156-1 and 156-2 can be strengthened to prevent product defects such as separation of the first electrode 154.

The reflective layer 154-1 in the first electrode 154 can be in contact with the first metal layer 156-1 on the side portion of the light emitting layer 150a, but may not be in contact with the second metal layer 156-2. That is, unlike FIG. 8, the size of the reflective layer 154-1 of the first electrode 154 can be reduced to the size of the first metal layer 156-1 on the side portion of the light emitting layer 150a. In this instance, the edge area 154b of the electrode layer 154-2 of the first electrode 154 can contact the second metal layer 156-2. Therefore, the lower side of the reflective layer can be in contact with the upper surface of the reflective layer 154-1 of the first electrode 154, and the lower side of the second metal layer 156-2 can be in contact with the upper surface of the electrode layer 154-2 of the first electrode 154. In addition, the lower side of the first insulating layer 157-1 can be in contact with the upper surface of the reflective layer 154-1 of the first electrode 154. The lower side of the second insulating layer 157-2 and/or the lower side of the third insulating layer 157-3 can be in contact with the electrode layer 154-2 of the first electrode 154.

Bonding performance was poor between the first metal layer 156-1 and the light emitting layer 150a and between the first metal layer 156-1 and the second metal layer 156-2. According to an embodiment, the first metal layer 156-1 can be spaced apart from the light emitting layer 150a. That is, the first insulating layer 157-1 can be disposed between the light emitting layer 150a and the first metal layer 156-1. The bonding performance of the first metal layer 156-1 with the light emitting layer 150a can be strengthened by the first insulating layer 157-1. Additionally, the second insulating layer 157-2 can be disposed between the first metal layer 156-1 and the second metal layer 156-2. The bonding performance of the second metal layer 156-2 with the first metal layer 156-1 can be strengthened by the second insulating layer 157-2. Therefore, the first metal layer 156-1 does not peel off from the light emitting layer 150a or the second metal layer 156-2 does not peel off from the first metal layer 156-1, thereby preventing product defects and improving reliability.

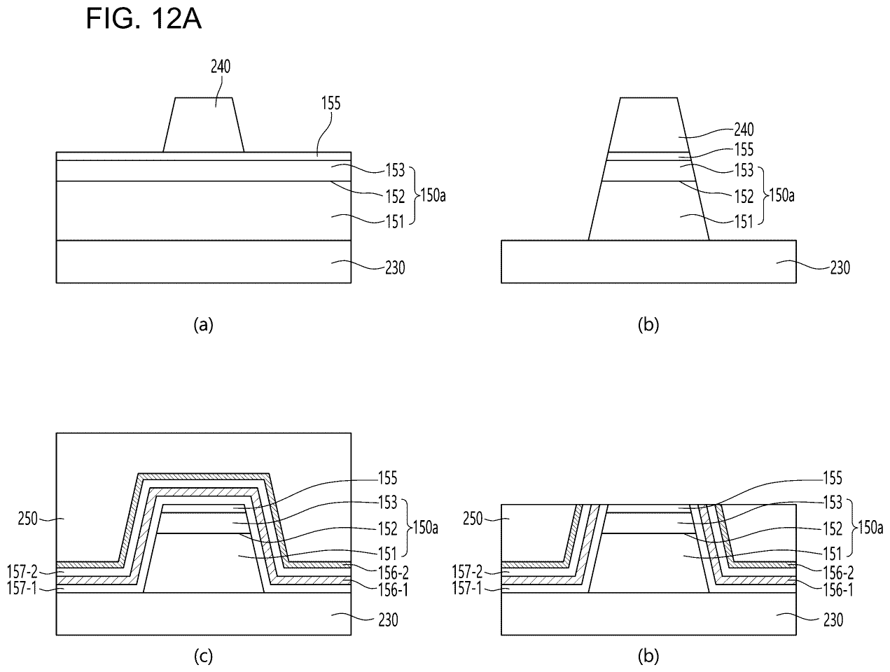

The plurality of metal layers 156-1 and 156-2 can have shapes corresponding to each other. When viewed three-dimensionally, the plurality of metal layers 156-1 and 156-2 can have a cylindrical structure, but is not limited thereto. For example, as shown in FIG. 11, the second metal layer 156-2 can have a cylindrical structure. Likewise, the first metal layer 156-1 can also have a cylindrical structure.

As shown in FIG. 9, when viewed from the bottom, the plurality of metal layers 156-1 and 156-2 can have a ring shape, but is not limited thereto. For example, the first metal layer 156-1 can have a ring shape. For example, the second metal layer 156-2 can have a ring shape.

The first metal layer 156-1 and the second metal layer 156-2 can have different thicknesses. The thickness of the second metal layer 156-2 can be thinner than the thickness of the first metal layer 156-1. For example, the thickness of the first metal layer 156-1 can be 50 nm to 300 nm. If the thickness of the first metal layer 156-1 is less than 50 nm, light can be transmitted and reflection efficiency can be reduced. When the thickness of the second metal layer 156-2 exceeds 300 nm, the size of the semiconductor light emitting device 150A can be increased. For example, the thickness of the second metal layer 156-2 can be 20 nm to 50 nm. When the thickness of the second metal layer 156-2 is less than 20 nm, the magnetization power of the second metal layer 156-2 can be weak, and the mobility of the semiconductor light emitting device 150A can be reduced, thereby reducing the assembly speed. When the thickness of the second metal layer 156-2 exceeds 50 nm, the magnetization force of the second metal layer 156-2 can be very strong. Therefore, during self-assembly, the semiconductor light emitting device 150A may not be assembled on the substrate, or the semiconductor light emitting device 150A assembled on the substrate can be separated from the substrate and moved toward the magnet. Therefore, assembly yield can decrease.

The insulating layer 157 can be made of a material with excellent insulating properties such that the light emitting layer 150A can be protected and leakage current flowing through the sides of the light emitting layer 150A can be prevented. In addition, the insulating layer 157 can be act as a repulsive force against the DEP force during self-assembly such that the first electrode 154 of the semiconductor light emitting device 150A can be properly assembled by facing the bottom surface of the assembly hole 340H on the backplane substrate (300A in FIG. 20, 301A in FIG. 22).

The insulating layer 157 can be disposed on the side portion of the light emitting layer 150A. The insulating layer 157 can surround the side portion of the light emitting layer 150A. The insulating layer 157 can be disposed along the perimeter of the side portion of the light emitting layer 150A. A portion of the insulating layer 157 can be disposed on the upper side of the second electrode 155. For example, a portion of the insulating layer 157 can vertically overlap the edge area 154b of the second electrode 155.

The insulating layer 157 may not be disposed on the lower side of the first electrode 154. As will be explained later, the insulating layer 157 and the first electrode 154 can be affected by DEP force. For example, with respect to DEP force, a pulling force can be applied to the first electrode 154 and a pushing force can be applied to the insulating layer 157.

A DEP force can be formed in the assembly hole 340H of the backplane substrate 300A and 301A, and the semiconductor light emitting device 150A can be located in the assembly hole 340H. In this instance, the first electrode 154 of the semiconductor light emitting device 150A can be pulled and the insulating layer 157 can be pushed by the DEP force formed in the assembly hole 340H, so that the first electrode 154 of the semiconductor light emitting device 150A can be assembled facing the bottom surface of the assembly hole 340H.

The insulating layer 157 can be separated by a plurality of metal layers 156-1 and 156-2. The insulating layer 157 can comprise a first insulating layer 157-1, a second insulating layer 157-2, and a third insulating layer 157-3.

The first insulating layer 157-1 can surround the side portion of the light emitting layer 150a. The first insulating layer 157-1 can be disposed along the perimeter of the side portion of the light emitting layer 150a. The first insulating layer 157-1 can be disposed between the light emitting layer 150a and the first metal layer 156-1, and the first metal layer 156-1 can be separated from the light emitting layer 150a by the light emitting layer 157-1. The first insulating layer 157-1 can be disposed between the side portion of the light emitting layer 150a and the side portion of the first metal layer 156-1. The first metal layer 156-1 can be disposed to be spaced apart from the side portion of the light emitting layer 150a. The first metal layer 156-1 can be spaced apart from the side portion of the light emitting layer 150a by the thickness of the first insulating layer 157-1.

The second insulating layer 157-2 can surround the side portion of the first metal layer 156-1. The second insulating layer 157-2 can be disposed along the perimeter of the side portion of the first metal layer 156-1. The second insulating layer 157-2 can be disposed between the first metal layer 156-1 and the second metal layer 156-2, and the second metal layer 156-2 can be separated from the first metal layer 156-1 by the second insulating layer 157-2. The second insulating layer 157-2 can be disposed between the side portion of the first metal layer 156-1 and the side portion of the second metal layer 156-2. The second metal layer 156-2 can be disposed to be spaced apart from the first metal layer 156-1. The second metal layer 156-2 can be spaced apart from the side portion of the first metal layer 156-1 by the thickness of the second insulating layer 157-2.

The third insulating layer 157-3 can surround the side portion of the second metal layer 156-2. The third insulating layer 157-3 can be disposed along the perimeter of the side portion of the second metal layer 156-2. The third insulating layer 157-3 can be disposed on the outside of the second metal layer 156-2. The third insulating layer 157-3 can be disposed on the outer side surface of the second metal layer 156-2.

A portion of the third insulating layer 157-3 can vertically overlap the upper side of the light emitting layer 150a. A portion of the third insulating layer 157-3 can vertically overlap the edge area 154b of the upper side of the light emitting layer 150a. A portion of the third insulating layer 157-3 can be disposed along the edge area 154b of the upper side of the light emitting layer 150a.

The first metal layer 156-1 and the second metal layer 156-2 may not be exposed to the outside by the third insulating layer 157-3. That is, the third insulating layer 157-3 can be disposed on the upper side of the first metal layer 156-1. The third insulating layer 157-3 can be disposed on the upper side of the second metal layer 156-2. Accordingly, the upper side of the first metal layer 156-1 and/or the upper side of the second metal layer 156-2 can be in contact with the third insulating layer 157-3. A portion of the third insulating layer 157-3 can be disposed on the edge area 154b of the upper side of the light emitting layer 150a from the side portion of the second metal layer 156-2 via the upper side of the second metal layer 156-2 and the upper side of the first metal layer 156-1.

The third insulating layer 157-3 can be in contact with the first insulating layer 157-1 and the second insulating layer 157-2. The third insulating layer 157-3 can be in contact with the upper side of the first insulating layer 157-1. The third insulating layer 157-3 can be in contact with the upper side of the second insulating layer 157-2. The upper sides of the first metal layer 156-1, the second metal layer 156-2, the first insulating layer 157-1, and the second insulating layer 157-2 can be positioned identically to each other. That is, the upper sides of each of the first metal layer 156-1, the second metal layer 156-2, the first insulating layer 157-1, and the second insulating layer 157-2 are located on the same horizontal line.

The first insulating layer 157-1, the second insulating layer 157-2, and the third insulating layer 157-3 can be formed of the same insulating material. For example, the first insulating layer 157-1, the second insulating layer 157-2, and the third insulating layer 157-3 can be formed of SiO2 or SiN2.

The first insulating layer 157-1, the second insulating layer 157-2, and the third insulating layer 157-3 can be formed of different insulating materials.

For example, the first insulating layer 157-1 can have a dielectric constant greater than that of the second insulating layer 157-2 or the third insulating layer 157-3. The DEP force formed on the substrate by the first insulating layer 157-1 becomes larger, so that the semiconductor light emitting device 150A can be assembled into the assembly hole more quickly, or the fixation of the semiconductor light emitting device 150A assembled in the assembly hole can be strengthened.

The second insulating layer 157-2 can be formed of an insulating material with excellent bonding performance with adjacent metal layers, for example, the first metal layer 156-1 and/or the second metal layer 156-2.

The third insulating layer 157-3 can be made of an insulating material with excellent insulating performance and durability. Leakage current of the light emitting layer 150a can be blocked by the third insulating layer 157-3, and the light emitting layer 150a can be physically or electrically protected from the outside.

The semiconductor light emitting device 150A can have a multi-stage structure. The multi-stage structure can be formed, for example, in the first conductivity type semiconductor light emitting device. For example, the multi-stage structure can be formed by having different areas or widths in the first conductivity type semiconductor layer 151. For example, the widths of the lower side and the upper side of the first conductivity type semiconductor layer 151 can be different. In this instance, a step can occur between the upper side of the first conductivity type semiconductor layer 151 and the lower side of the first conductivity type semiconductor layer 151. That is, the upper surface of the edge region 154b of the lower side of the first conductivity type semiconductor layer 151 does not overlap with the upper side of the first conductivity type semiconductor layer 151, so it can be exposed to the outside.

Due to the multi-stage structure of the semiconductor light emitting device 150A, assembly defects can be prevented during self-assembly. That is, due to the multi-stage structure of the semiconductor light emitting device 150A, during self-assembly, the semiconductor light emitting device 150A can be moved to the proper position without being significantly shaken up and down or turned over, thereby preventing assembly defects. Since assembly defects are prevented, lighting defects can also be prevented.

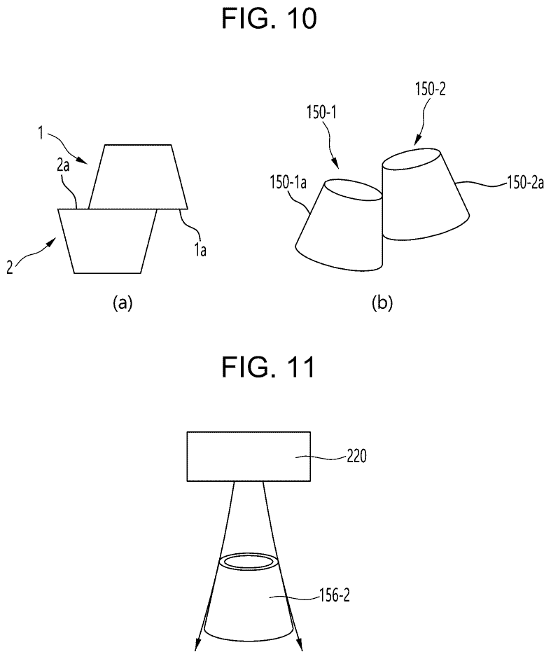

FIG. 10 shows adjacent semiconductor light emitting devices sticking together in each of a comparative example and the embodiment.

As shown in FIG. 10A, in the comparative example, a magnetic layer is disposed on the lower side of the light emitting layer 150a. When the magnet moves during self-assembly, the semiconductor light emitting devices 1 and 2 in the fluid can move toward the magnet. Since a magnetic layer is provided on the lower side of each of the semiconductor light emitting devices 1 and 2 and the lower surfaces 1a and 2a thereof have a flat surface, the semiconductor light emitting devices 1 and 2 stick to each other. That is, the magnetic layer on the lower side of each of the semiconductor light emitting devices 1 and 2 and the lower surfaces 1a and 2a of the semiconductor light emitting devices 1 and 2 come into surface contact with each other, so that the stuck semiconductor light emitting devices 1 and 2 do not separate from each other. Surrounding semiconductor light emitting devices adhere to the semiconductor light emitting devices 1 and 2, resulting in agglomeration phenomenon in the form of lumps. In this instance, there is a problem that not only the assembly speed is lowered, but also the assembly yield and lighting efficiency are reduced.

However, as shown in FIG. 10B, in an embodiment, the magnetic layer may not be disposed on the lower side of the light emitting layer 150a. In an embodiment, a magnetic layer can be disposed on the side surfaces 150-1a and 150-2a of the light emitting layer 150a. Therefore, during self-assembly, the side surfaces 150-1a and 150-2a of the semiconductor light emitting devices 150-1 and 150-2 that are moving by the magnet can stick to each other. However, since each side surface of the light emitting layer 150a, the insulating layer 157, and the metal layers 156-1 and 156-2 has a round surface with a predetermined curvature, the side surfaces 150-1a and 150-2a of adjacent semiconductor light emitting devices 150-1 and 150-2 can be in line contact with each other.

Accordingly, the stuck semiconductor light emitting devices 150-1 and 150-2 can immediately fall off and be quickly and accurately moved to a desired location on the substrate by the magnet. Therefore, the assembly speed of the semiconductor light emitting devices 150-1 and 150-2 can be increased. In addition, assembly yield and lighting efficiency can be improved. That is, the agglomeration phenomenon in the form of a lump does not occur, so that one semiconductor light emitting device 150-1 and 150-2 can be properly assembled in each assembly hole on the substrate, and electrical connection defects do not occur with the properly-assembled semiconductor light emitting devices 150-1 and 150-2. Thus, assembly yield and lighting efficiency can be improved.

FIG. 11 shows the magnetic field of a magnet being applied to a cylindrical structure of the second metal layer.

As shown in FIG. 11, the second metal layer 156-2 comprising a magnetic layer can have a cylindrical structure. During self-assembly, the magnet 220 can be positioned on the second metal layer 156-2. The magnets 220 can be included in the assembly device 1100 shown in FIG. 7 and can be provided in plural. In this instance, the magnetic field generated by the magnet 220 can be applied to the cylindrical structure of the second metal layer 156-2, thereby magnetizing the second metal layer 156-2. In this instance, since the cylindrical structure of the second metal layer 156-2 is magnetized, when the magnet 220 moves in a direction parallel to the surface of the substrate, the semiconductor light emitting device 150A comprising the second metal layer 156-2 can be moved stably and balanced to a desired location on the substrate.

Magnet 220 can be located below second metal layer 156-2.

According to an embodiment, the semiconductor light emitting devices may not aggregate in the fluid during self-assembly. A plurality of metal layers 156-1 and 156-2 can be disposed on the side portion of the light emitting layer 150a, and one of the plurality of metal layers 156-1 and 156-2 can comprise a magnetic layer. The side surface of the magnetic layer disposed on the side portion of the light emitting layer 150a can have a round surface. The semiconductor light emitting devices 150-1 and 150-2 can be moved in the fluid by the magnet 220, and the semiconductor light emitting devices 150-1 and 150-2 can be attached to each other by the respective magnetic layers of the semiconductor light emitting devices 150-1 and 150-2. However, since the semiconductor light emitting devices 150-1 and 150-2 are in line contact through the side portion provided with the magnetic layer, the stuck semiconductor light emitting devices 150-1 and 150-2 can immediately fall off, the stuck semiconductor light emitting devices 150-1 and 150-2 can immediately fall off and an agglomerate phenomenon does not occur. Therefore, the semiconductor light emitting devices 150-1 and 150-2 do not aggregate and are individually moved within the fluid such that the assembly speed of the semiconductor light emitting devices 150-1 and 150-2 can be increased, and the assembly yield and lighting yield can be improved.

According to the embodiment, since one of the plurality of metal layers 156-1 and 156-2 disposed on the side portion of the light emitting layer 150a comprise a reflective layer, light output efficiency can be improved by the reflective layer 156-1, thereby increasing luminance.

### [Manufacturing Process of Semiconductor Light Emitting Device]

(a) to (d) of FIG. 12A and (c) to (g) of FIG. 12B's illustrate the manufacturing process of the semiconductor light emitting device according to the first embodiment.

As shown in (a) of FIG. 12A, the light emitting layer 150A can be deposited on a growth substrate 230. The growth substrate 230 can be formed of sapphire, GaN, glass, silicon, ceramic, etc. The light emitting layer 150A can comprise at least one or more first conductivity type semiconductor layer 151, an active layer 152, and at least one or more second conductivity type semiconductor layer 153. The first conductivity type semiconductor layer 151 can comprise an n-type dopant, and the second conductivity type semiconductor layer 153 can comprise a p-type dopant.

The second electrode 155 can be formed on the light emitting layer 150A, that is, the second conductivity type semiconductor layer 153. Since the light of the active layer 152 must be emitted forward, the second electrode 155 can be made of a transparent conductive material, for example, ITO, IZO, etc. A photosensitive film can be formed on the second electrode 155 and patterned to form a photosensitive pattern 240. That is, the photosensitive pattern 240 can be formed by removing the remaining photosensitive film except for the area to be mesa patterned.

As shown in (b) of FIG. 12A, an etching process can be performed using the photosensitive pattern 240 as a mask to remove the second electrode 155 and the light emitting layer 150A. Since the photosensitive pattern 240 is used as a mask, a mesa-patterned light emitting layer 150A having a size corresponding to the photosensitive pattern 240 can be formed. The mesa-patterned light emitting layer 150A can be called a chip. The etching process can be a dry etching process, and the mesa patterned light emitting layer 150A can be formed by etching obliquely rather than vertically. The photosensitive pattern 240 can be removed.

As shown in (c) of FIG. 12A, after the first insulating layer 157-1, the first metal layer 156-1, the second insulating layer 157-2, and the second metal layer 156-2 can be sequentially formed, a photosensitive film 250 can be formed on the second metal layer 156-2.

For example, the first metal layer 156-1 can comprise a reflective layer. For example, the second metal layer 156-2 can comprise a magnetic layer. The first insulating layer 157-1 and the second insulating layer 157-2 can be made of different insulating materials. For example, the first insulating layer 157-1 can have a dielectric constant greater than that of the second insulating layer 157-2. The second insulating layer 157-2 can be made of an insulating material with excellent bonding performance.

As shown in (d) of FIG. 12A, an ashing process can be performed to form the photosensitive pattern 250a. The ashing process can be performed until the upper surface of the photosensitive pattern 250a matches the upper surface of the second electrode 155. Accordingly, after the ashing process is performed, the upper surface of the photosensitive pattern 250a can match the upper surface of the second electrode 155. The second metal layer 156-2 can be exposed.

A first etching process can be performed to remove the exposed second metal layer 156-2. By removing the second metal layer 156-2, the second insulating layer 157-2 can be exposed. A second etching process can be performed to remove the exposed second insulating layer 157-2. By removing the second insulating layer 157-2, the first metal layer 156-1 can be exposed. A third etching process can be performed to remove the exposed first metal layer 156-1. By removing the first metal layer 156-1, the first insulating layer 157-1 can be exposed. A fourth etching process can be performed to remove the exposed first insulating layer 157-1. By removing the first insulating layer 157-1, the upper surface of the second electrode 155 can be exposed. The first etching process and the third etching process can be an etching process to remove metal, and the second etching process and the fourth etching process can be an etching process to remove an inorganic insulating material.

As shown in (c) FIG. 12B, a third insulating layer 157-3 can be formed on the exposed second metal layer 156-2, the second insulating layer 157-2, the first metal layer 156-1, and the first insulating layer 157-1. The third insulating layer 157-3 can be formed on the second electrode 155. The insulating layer 157 can be composed of the first insulating layer 157-1, the second insulating layer 157-2, and the third insulating layer 157-3. The upper side of the first metal layer 156-1 and/or the second metal layer 156-2 can be in contact with the third insulating layer 157-3. The upper side of the first insulating layer 157-1 and/or the second insulating layer 157-2 can be in contact with the third insulating layer 157-3.

As shown in (f) of FIG. 12B, an etching process can be performed to remove a portion of the third insulating layer 157-3 on the second electrode 155. Accordingly, an opening 158 can be formed through which the second electrode 155 corresponding to the portion of the removed third insulating layer 157-3 is exposed.

The process of forming the opening 158 on the second electrode 155 can be omitted. As an example, after the semiconductor light emitting device 150A is assembled on a backplane substrate (300A in FIG. 20, 301A in FIG. 22), a process of forming the opening 158 on the second electrode 155 of the semiconductor light emitting device 150A can be performed. As another example, after the semiconductor light emitting device 150A is assembled on the backplane substrate (300A in FIG. 20, 301A in FIG. 22) and the second insulating layer (350 in FIG. 19, 350 in FIG. 21) is formed, when a contact hole for forming the electrode wiring 360 is formed in the second insulating layer 157-2, the third insulating layer 157-3 of the semiconductor light emitting device 150A can be removed and the opening 158 can be formed together. That is, the contact hole and opening 158 can be formed through the same etching process.

Thereafter, the growth substrate 230 can be attached to the temporary substrate 260 using the adhesive layer 270. The adhesive layer 270 can be formed of an organic insulating material, but is not limited thereto. The adhesive layer 270 can be formed of a metal such as aluminum (Al). A sacrificial layer can be formed on the adhesive layer 270 with a metal such as aluminum (Al). In this instance, the adhesive layer 270 can contact the third insulating layer 157-3 and the second electrode 155, and the sacrificial layer can contact the temporary substrate 260.

Afterwards, a laser lift off (LLO) process can be performed to remove the growth substrate 230. After the growth substrate 230 is removed, a cleaning process, a polishing process, a drying process, etc., to remove foreign substances can be performed. In addition, when an undoped layer is formed as part of the light emitting layer 150A in contact with the growth substrate 230, the undoped layer can be removed through an etching process.

By removing the growth substrate 230, the mesa patterned light emitting layer 150A, that is, the first insulating layer 157-1, the first metal layer 156-1, the second insulating layer 157-2, the second metal layer 156-2, and the third insulating layer 157-3 located between chips can be removed. In addition, the first insulating layer 157-1, the first metal layer 156-1, the second insulating layer 157-2, the second metal layer 156-2, and the third insulating layer 157-3 can remain on the side portion of the light emitting layer 150a.

Thereafter, the first electrode 154 can be formed on the lower surface of the light emitting layer 150a exposed by removing the growth substrate 230. The first electrode 154 can have a multilayer structure comprising a plurality of layers. For example, the first electrode 154 can comprise a reflective layer 154-1, an electrode layer 154-2, etc.

Thereafter, as shown in (g) of FIG. 12B, the adhesive layer 270 can be removed, so that the temporary substrate 260 can be separated and the semiconductor light emitting device 150A according to the first embodiment can be manufactured. Accordingly, the semiconductor light emitting device 150A according to the first embodiment can comprise the light emitting layer 150a, the first electrode 154, the second electrode 155, the insulating layer 157, and the plurality of metal layers 156-1 and 156-2.

### Second Embodiment

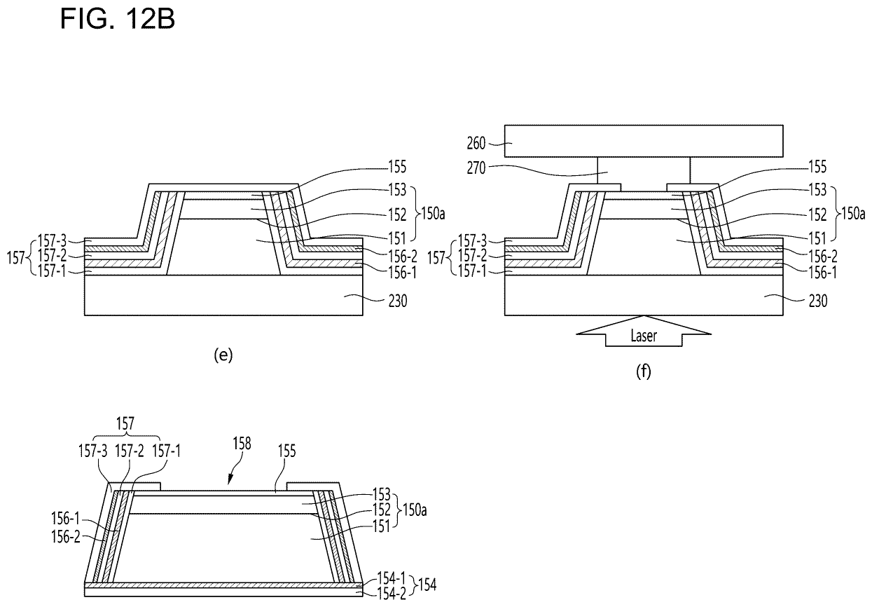

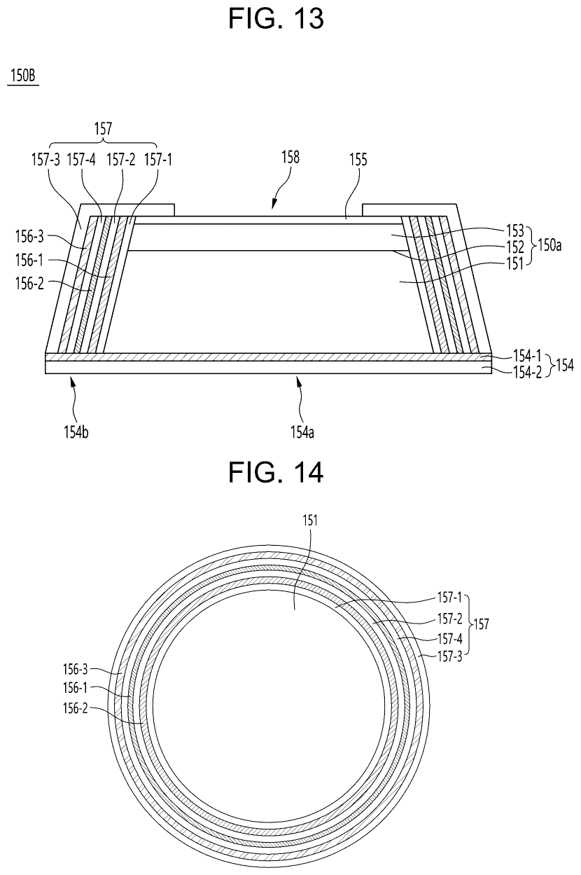

FIG. 13 is a cross-sectional view illustrating a semiconductor light emitting device according to a second embodiment. FIG. 14 is a bottom view illustrating the semiconductor light emitting device according to the second embodiment after the first electrode has been removed.

The second embodiment is the same as the first embodiment except for the third metal layer 156-3 and the fourth insulating layer 157-4. In the second embodiment, components having the same structure, shape and/or function as those of the first embodiment are given the same reference numerals, and detailed descriptions are omitted.

Referring to FIG. 13, the semiconductor light emitting device 150B according to the second embodiment can comprise a light emitting layer 150A, a first electrode 154, a second electrode 155, an insulating layer 157, and a plurality of metal layers 156-1 to 156-3. The semiconductor light emitting device 150B according to the second embodiment can comprise more components than these.

The first electrode 154 can be disposed on the lower side of the light emitting layer 150a, and the second electrode 155 can be disposed on the upper side of the light emitting layer 150a.

A plurality of metal layers 156-1 to 156-3 can surround the light emitting layer 150a. The plurality of metal layers 156-1 to 156-3 can be disposed to be spaced apart from each other. That is, the plurality of metal layers 156-1 to 156-3 may not be in contact with each other. The plurality of metal layers 156-1 to 156-3 can have corresponding shapes. The plurality of metal layers 156-1 to 156-3 can have a cylindrical structure when viewed three-dimensionally. The plurality of metal layers 156-1 to 156-3 can have a ring shape when viewed from the bottom.

The plurality of metal layers 156-1 to 156-3 can comprise at least one or more first metal layer 156-1, at least one or more second metal layer 156-2, and at least one or more third metal layer 156-3.

The first metal layer 156-1 can be disposed closer to the light emitting layer 150a than the second metal layer 156-2 or the third metal layer 156-3. The first metal layer 156-1 can comprise a reflective layer.

The second metal layer 156-2 can be disposed to be spaced outwardly from the first metal layer 156-1.

The third metal layer 156-3 can be disposed to be spaced outwardly from the second metal layer 156-2. The third metal layer 156-3 can comprise a reflective layer.

As shown in FIG. 14, the first metal layer 156-1, the second metal layer 156-2, and the third metal layer 156-3 can have shapes corresponding to each other. For example, the first metal layer 156-1, the second metal layer 156-2, and the third metal layer 156-3 can have a ring shape when viewed from the bottom, but is not limited thereto. The second metal layer 156-2 can be disposed between the first metal layer 156-1 and the third metal layer 156-3. The second metal layer 156-2 can surround the first metal layer 156-1. The third metal layer 156-3 can surround the second metal layer 156-2.

The first metal layer 156-1 can serve to improve light output efficiency by more easily extracting light generated inside the light emitting layer 150a to the outside. The third metal layer 156-3 can serve to reflect light incident from the outside into the inside of the display device (FIGS. 19 and 21) back to the outside.

In the drawing, the first metal layer 156-1 and the third metal layer 156-3 are shown as having the same acute angle with respect to the lower surface of the light emitting layer 150a, but the first metal layer 156-1 and the third metal layer 156-3 can be inclined at different angles.

As an example, the upper side of at least one or more layer of the first metal layer 156-1, the second metal layer 156-2, and the third metal layer 156-3 can coincide with the upper surface of the second electrode 155. As another example, the upper side of at least one or more layer of the first metal layer 156-1, the second metal layer 156-2, and the third metal layer 156-3 can be located higher than the upper surface of the second conductivity type semiconductor layer 153 of the light emitting layer 150a.

The insulating layer 157 can surround the light emitting layer 150a. A plurality of metal layers 156-1 to 156-3 can be separated by an insulating layer 157.

The insulating layer 157 can comprise a first insulating layer 157-1, a second insulating layer 157-2, a third insulating layer 157-3, and a fourth insulating layer 157-4. The first insulating layer 157-1 can be disposed between the light emitting layer 150a and the first metal layer 156-1. The second insulating layer 157-2 can be disposed between the first metal layer 156-1 and the second metal layer 156-2. The third insulating layer 157-3 can be disposed on the outer side surface of the third metal layer 156-3. The fourth insulating layer 157-4 can be disposed between the second metal layer 156-2 and the third metal layer 156-3.

A portion of the third insulating layer 157-3 can be disposed on the edge area 154b of the second metal layer 156-2. For example, a portion of the third insulating layer 157-3 can vertically overlap the edge region 154b of the second metal layer 156-2. For example, a portion of the third insulating layer 157-3 can be disposed on the edge area 154b of the second metal layer 156-2 via the third metal layer 156-3, the fourth insulating layer 157-4, the second metal layer 156-2, the second insulating layer 157-2, the first metal layer 156-1 and the first insulating layer 157-1 on the outer side surface of the third metal layer 156-3.

As an example, the upper side of at least one or more layer of the first metal layer 156-1, the second metal layer 156-2, and the third metal layer 156-3 can be in contact with the third insulating layer 157-3. As another example, the upper side of at least one or more layer of the first insulating layer 157-1, the second insulating layer 157-2, and the fourth insulating layer 157-4 can be in contact with the third insulating layer 157-3.

At least one more layer of the plurality of metal layers 156-1 to 156-3 can be in contact with the first electrode 154.

As an example, the lower side of the first metal layer 156-1 can be in contact with the upper surface of the reflective layer 154-1 of the first electrode 154. The first metal layer 156-1 can comprise a reflective layer, and since the first metal layer 156-1 and the reflective layer 154-1 of the first electrode 154 can be in contact with each other, the light generated inside the light emitting layer 150a may not be transmitted through between the first metal layer 156-1 and the reflective layer 154-1 of the first electrode 154. This arrangement can maximize reflection efficiency and increase luminance.

As another example, the lower side of the second metal layer 156-2 can contact the upper surface of the reflective layer 154-1 of the first electrode 154. As another example, the lower side of the third metal layer 156-3 can be in contact with the upper surface of the reflective layer 154-1 of the first electrode 154.

The insulating layer 157 can be in contact with the first electrode 154. At least one or more layer of the first insulating layer 157-1, the second insulating layer 157-2, and the third insulating layer 157-3 can be in contact with the first electrode 154.

As an example, the lower side of the first insulating layer 157-1 can be in contact with the upper surface of the reflective layer 154-1 of the first electrode 154. As another example, the lower side of the second insulating layer 157-2 can contact the upper surface of the reflective layer 154-1 of the first electrode 154. As another example, the lower side of the third insulating layer 157-3 can be in contact with the upper surface of the reflective layer 154-1 of the first electrode 154.

The first metal layer 156-1, the second metal layer 156-2, and/or the third metal layer 156-3 can have poor bonding performance with the first electrode 154. Accordingly, at least one or more layer of not only the first metal layer 156-1, the second metal layer 156-2, and the third metal layer 156-3, but also the first insulating layer 157-1, the second insulating layer 157-2, and the third insulating layers 157-3 can be in contact with the first electrode 154 such that bonding performance between the first electrode 154 and the plurality of metal layers 156-1 to 156-3 can be strengthened, and product defects such as separation of the first electrode 154 can be prevented.

The reflective layer 154-1 in the first electrode 154 can be in contact with the first metal layer 156-1 on the side portion of the light emitting layer 150a, but may not be in contact with the second metal layer 156-2 and/or the third metal layer 156-3. That is, unlike FIG. 8, the size of the reflective layer 154-1 of the first electrode 154 can be reduced to the size of the first metal layer 156-1 on the side portion of the light emitting layer 150a. In this instance, the edge area 154b of the electrode layer 154-2 of the first electrode 154 can contact the second metal layer 156-2 and/or the third metal layer 156-3. Accordingly, the lower side of the first metal layer 156-1 can be in contact with the upper surface of the reflective layer 154-1 of the first electrode 154, and the lower side of the second metal layer 156-2 and/or the lower side of the third metal layer 156-3 can be in contact with the upper surface of the reflective layer 154-1 of the first electrode 154. The electrode 154 can be in contact with the upper surface of the electrode layer 154-2. In addition, the lower side of the first insulating layer 157-1 can be in contact with the upper surface of the reflective layer 154-1 of the first electrode 154. The lower side of the second insulating layer 157-2 and/or the lower side of the third insulating layer 157-3 can be in contact with the electrode layer 154-2 of the first electrode 154.

According to the embodiment, the second metal layer 156-2 is provided to prevent an agglomeration phenomenon between the semiconductor light emitting devices 150B during self-assembly. Accordingly, the assembly speed can be increased, and the assembly yield and lighting efficiency can be improved.

According to the embodiment, the first metal layer 156-1 can be provided so that light inside the semiconductor light emitting device 150B can be easily extracted to the outside, thereby improving light output efficiency and increasing brightness.

According to an embodiment, the third metal layer 156-3 can be provided so that light incident from the outside to the inside of the display device can be reflected back to the outside, so that the luminance can be further increased. Since the third metal layer 156-3 is provided in the semiconductor light emitting device 150B, there is no need to provide a separate reflective layer in the display device, simplifying the structure and reducing manufacturing costs.

### Third Embodiment

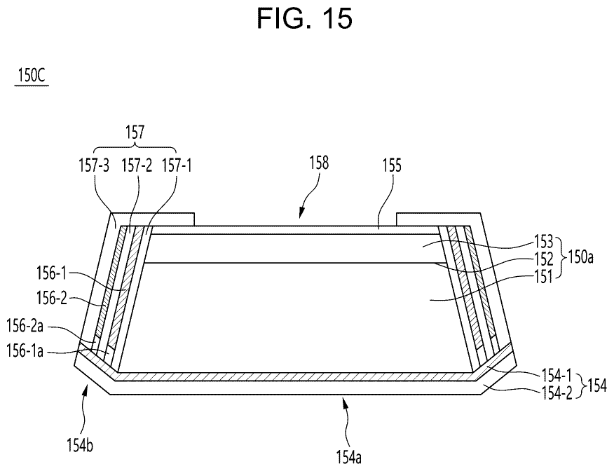

FIG. 15 is a cross-sectional view illustrating a semiconductor light emitting device according to a third embodiment.

The third embodiment is the same as the first embodiment except for a structure in which the plurality of metal layers 156-1 and 156-2 do not contact the first electrode 154. The third embodiment can be equally applied to the second embodiment. In the third embodiment, components having the same structure, shape and/or function as those of the first embodiment are given the same reference numerals, and detailed descriptions are omitted.

Referring to FIG. 15, the semiconductor light emitting device 150C according to the third embodiment can comprise a light emitting layer 150A, a first electrode 154, a second electrode 155, an insulating layer 157, and a plurality of metal layers 156-1 and 156-2. The semiconductor light emitting device 150C according to the third embodiment can comprise more components than these.

A plurality of metal layers 156-1 and 156-2 can be disposed on the side portion of the light emitting layer 150a. A plurality of metal layers 156-1 and 156-2 can be disposed along the perimeter of the side portion of the light emitting layer 150a. For example, the first metal layer 156-1 and the second metal layer 156-2 can be disposed along the perimeter of the side portion of the light emitting layer 150a.

The insulating layer 157 can be disposed on the side portion of the light emitting layer 150a. The insulating layer 157 can be disposed along the perimeter of the side portion of the light emitting layer 150a. A plurality of metal layers 156-1 and 156-2 can be disposed on the insulating layer 157. A portion of the insulating layer 157 can be disposed on the edge area 154b of the second electrode 155 via the plurality of metal layers 156-1 and 156-2.

For example, the first metal layer 156-1 and the second metal layer 156-2 can be disposed to be spaced apart from each other in the insulating layer 157. The first metal layer 156-1 and the second metal layer 156-2 can be separated from each other by the first insulating layer 157-1, the second insulating layer 157-2, and the third insulating layer 157-3. The first metal layer 156-1 can be disposed between the first insulating layer 157-1 and the second insulating layer 157-2, and the second metal layer 156-2 can be disposed between the second insulating layer 157-2 and the third insulating layer 157-3. The first insulating layer 157-1 can be disposed closer to the side portion of the light emitting layer 150a than the second insulating layer 157-2 or the third insulating layer 157-3.

The upper side of at least one or more layer of the plurality of metal layers 156-1 and 156-2 can coincide with the upper side of the insulating layer 157, but the lower side of at least one or more layer of the plurality of metal layers 156-1 and 156-2 may not coincide with the upper side of the insulating layer 157. That is, the lower side of at least one or more layer of the plurality of metal layers 156-1 and 156-2 can be positioned higher than the lower side of the insulating layer 157. In other words, the width of at least one or more layer of the plurality of metal layers 156-1 and 156-2 can be smaller than the width of the insulating layer 157.

For example, the lower side of the first metal layer 156-1 can be positioned higher than the lower side of the first insulating layer 157-1 and/or the lower side of the second insulating layer 157-2. Accordingly, a space 156-1a can be formed between the lower side of the first insulating layer 157-1 and the lower side of the second insulating layer 157-2. For example, the lower side of the second metal layer 156-2 can be positioned higher than the lower side of the second insulating layer 157-2 and/or the lower side of the third insulating layer 157-3. Accordingly, a space 156-2a can be formed between the lower side of the second insulating layer 157-2 and the lower side of the third insulating layer 157-3. Air can be filled in the corresponding space 156-1a and 156-2a, but is not limited thereto.

In this instance, the first electrode 154 may not be in contact with the first metal layer 156-1 and/or the second metal layer 156-2. That is, the first electrode 154 can be spaced apart from the first metal layer 156-1 and/or the second metal layer 156-2 through the space 156-1a and 156-2a.

For example, the reflective layer 154-1 of the first electrode 154 can be spaced apart from the first metal layer 156-1 through the space 156-1a. For example, the reflective layer 154-1 of the first electrode 154 can be spaced apart from the second metal layer 156-2 through the space 156-2a.

According to the embodiment, since the first electrode 154 does not contact the plurality of metal layers 156-1 and 156-2, the first electrode 154 may not be electrically connected to the plurality of metal layers 156-1 and 156-2. Therefore, by preventing the current flowing from the light emitting layer 150a to the first electrode 154 from unnecessarily flowing into the plurality of metal layers 156-1 and 156-2, electrical and optical properties can be improved.

According to the embodiment, in an outward direction from the side portion of the light emitting layer 150a, a first insulating layer 157-1, a space 156-1a formed by the first metal layer 156-1, a second insulating layer 157-2, a space 156-2a formed by the second metal layer 156-2, and a third insulating layer 157-3 can be disposed. Therefore, the first insulating layer 157-1, the space 156-1a, the second insulating layer 157-2, the space 156-2a, and the third insulating layer 157-3 has different refractive indices such that the reflection efficiency of light generated inside the light emitting layer 150a can be further improved, and high brightness can be realized.

The lower surface of at least one or more layer of the first metal layer 156-1, the second metal layer 156-2, the first insulating layer 157-1, the second insulating layer 157-2, and the third insulating layers 157-3 can be inclined with respect to the lower surface of the light emitting layer 150a. The lower surface of each of the first metal layer 156-1, the second metal layer 156-2, the first insulating layer 157-1, the second insulating layer 157-2, and the third insulating layer 157-3 can be inclined at the same angle with respect to the lower surface of the light emitting layer 150a, but is not limited thereto.

The shape of the edge area 154b of the first electrode 154 can correspond to the shape of the lower sides of the plurality of metal layers 156-1 and 156-2 and the insulating layer 157 disposed on the side portion of the light emitting layer 150a, the edge area 154b of the first electrode 154 can also be inclined with respect to the lower surface of the light emitting layer 150a. The edge area 154b of the first electrode 154 can have an obtuse angle with respect to the lower surface of the light emitting layer 150a.

Therefore, since the center area 154a of the first electrode 154 has a flat surface and the edge area 154b of the first electrode 154 has an inclined surface, the size of the first electrode 154 can be increased compared to the first and second embodiments. An increase in the size of the first electrode 154 can lead to an increase in DEP force during self-assembly, thereby improving assembly yield and lighting efficiency.

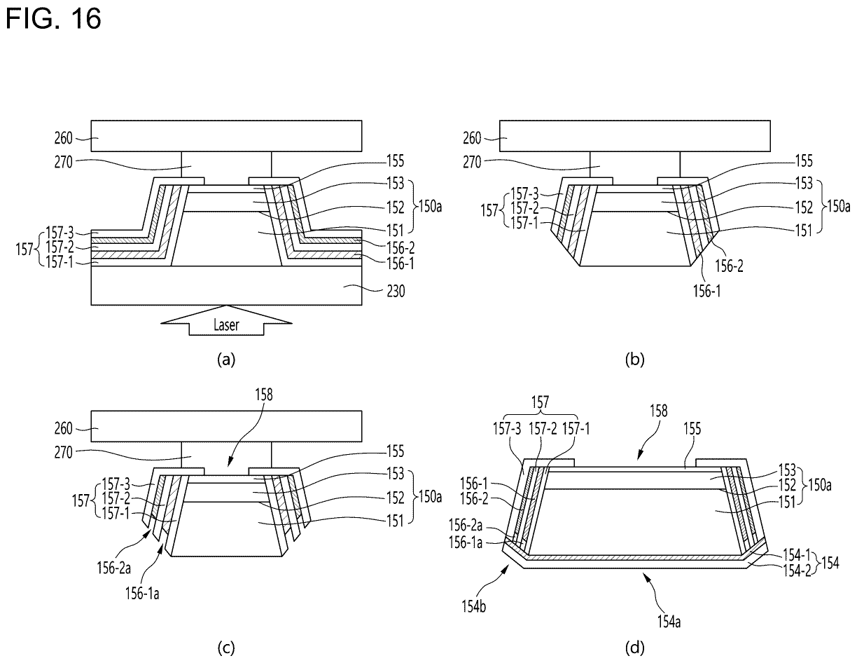

FIG. 16 illustrates a manufacturing process of a semiconductor light emitting device according to the third embodiment.

(a) of FIG. 16 is the same as FIG. 12B's (f). Therefore, the manufacturing process before (a) of FIG. 16 can be easily understood from the manufacturing process of (a) of FIG. 12A to (c) of FIG. 12B, and detailed description is omitted.

As shown in (a) of FIG. 16, the growth substrate 230 can be removed using the LLO process.

Accordingly, as shown in (b) of FIG. 16, the lower side of the plurality of metal layers 156-1 and 156-2 and the insulating layer 157 disposed on the side portion of the light emitting layer 150a can be inclined to the lower surface of the light emitting layer 150a.

By irradiating a laser using the LLO process between the growth substrate 230 and the lower surface of the light emitting layer 150a, the light emitting layer 150a can be separated from the growth substrate 230. Since the laser is not irradiated between the insulating layer 157, that is, the lower surface of the first insulating layer 157-1 and the growth substrate 230, the insulating layer 157 may not be separated from the growth substrate 230. Accordingly, while the light emitting layer 150a is easily separated from the growth substrate 230, the insulating layer 157 on the side portion of the light emitting layer 150a is not separated from the growth substrate 230. The insulating layer 157 on the light emitting layer 150a can be separated from the growth substrate 230 together with the light emitting layer 150a, and the insulating layer 157 on the side portion of the light emitting layer 150a can remain on the growth substrate 230 as is. Accordingly, a structure as shown in (b) of FIG. 16 can be obtained.

As shown in (c) of FIG. 16, an etching process can be performed to partially remove the lower side of the first metal layer 156-1 and/or the second metal layer 156-2 to form a space 156-1a and 156-2a.

As shown in (d) of FIG. 16, the first electrode 154 can be formed on the lower side of the light emitting layer 150a, the lower side of the insulating layer 157, and the lower side of the plurality of metal layers 156-1 and 156-2 such that a semiconductor light emitting device 150C according to the third embodiment can be manufactured.

### Fourth Embodiment

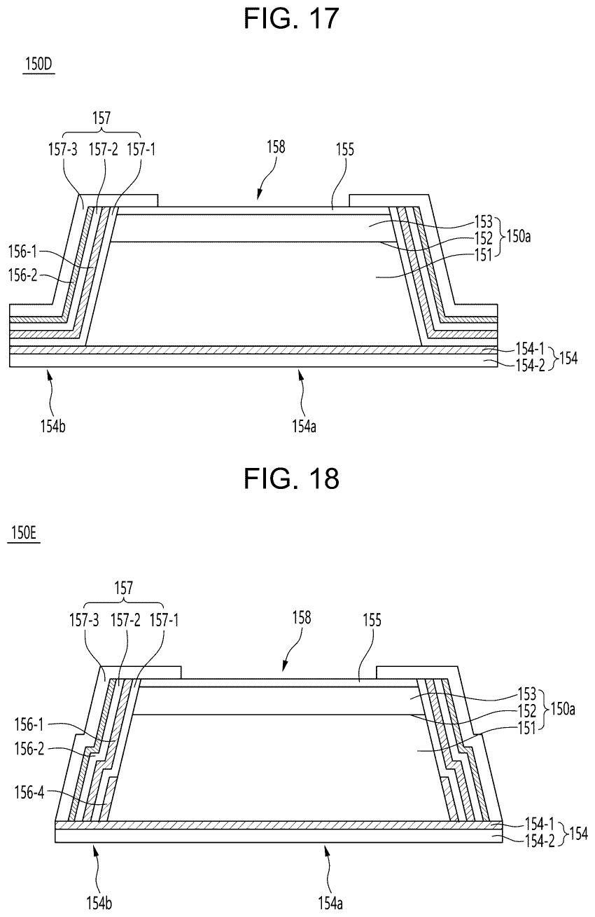

FIG. 17 is a cross-sectional view illustrating a semiconductor light emitting device according to a fourth embodiment.

The fourth embodiment is the same as the first embodiment except for a structure in which the plurality of metal layers 156-1 and 156-2 do not contact the first electrode 154. The fourth embodiment can be equally applied to the second embodiment. In the fourth embodiment, components having the same structure, shape, and/or function as those of the first embodiment are given the same reference numerals, and detailed descriptions are omitted.

Referring to FIG. 17, the semiconductor light emitting device 150D according to the fourth embodiment can comprise a light emitting layer 150A, a first electrode 154, a second electrode 155, an insulating layer 157, and a plurality of metal layers 156-1 and 156-2. The semiconductor light emitting device 150D according to the fourth embodiment can comprise more components than these.

The plurality of metal layers 156-1 and 156-2 can be disposed on the side portion of the light emitting layer 150a. The plurality of metal layers 156-1 and 156-2 can be disposed along the perimeter of the side portion of the light emitting layer 150a. For example, the first metal layer 156-1 and the second metal layer 156-2 can be disposed along the perimeter of the side portion of the light emitting layer 150a.

The plurality of metal layers 156-1 and 156-2 can have a bent structure. The insulating layer 157 can have a bent structure. The plurality of metal layers 156-1 and 156-2 can have shapes corresponding to each other. The plurality of metal layers 156-1 and 156-2 and the insulating layer 157 can have shapes corresponding to each other.

The plurality of metal layers 156-1 and 156-2 can be disposed in parallel on the side portion of the light emitting layer 150a and bent from the lower side of the light emitting layer 150a toward an outward direction. The plurality of metal layers 156-1 and 156-2 can be bent from the lower side of the light emitting layer 150a toward an outward direction and disposed parallel to the first electrode 154. The insulating layer 157 can be disposed parallel to the side portion of the light emitting layer 150a and can be bent from the lower side of the light emitting layer 150a toward an outward direction. The insulating layer 157 can be bent from the lower side of the light emitting layer 150a toward an outward direction and disposed parallel to the first electrode 154.

The first metal layer 156-1 can be disposed parallel to the side portion of the light emitting layer 150a and can be disposed parallel to the first electrode 154 on the lower side of the light emitting layer 150a. In this instance, the first metal layer 156-1 can comprise a 1-1 metal layer disposed parallel to the side portion of the light emitting layer 150a and a 1-2 metal layer bent from the bottom of the 1-1 metal layer toward an outward direction and disposed parallel to the first electrode 154. The 1-2 metal layer can be spaced apart from the first electrode 154 through the first insulating layer 157-1. The first insulating layer 157-1 can be disposed between the 1-2 metal layer and the reflective layer 154-1 of the first electrode 154. Accordingly, the first electrode 154 can be spaced apart from the first metal layer 156-1 without being in contact with the first metal layer 156-1.

Each of the second insulating layer 157-2, the second metal layer 156-2, and the third insulating layer 157-3 can have a shape corresponding to the shape of the first metal layer 156-1.

According to the embodiment, since the first electrode 154 does not contact the plurality of metal layers 156-1 and 156-2, the first electrode 154 may not be electrically connected to the plurality of metal layers 156-1 and 156-2. Therefore, by preventing the current flowing from the light emitting layer 150a to the first electrode 154 from unnecessarily flowing into the plurality of metal layers 156-1 and 156-2, electrical and optical properties can be improved.

### Fifth Embodiment

FIG. 18 is a cross-sectional view illustrating a semiconductor light emitting device according to a fifth embodiment. The fifth embodiment is the same as the first embodiment except for the fourth metal layer 156-4. The fifth embodiment can be equally applied to the second to fourth embodiments. In the fifth embodiment, components having the same structure, shape, and/or function as those of the first embodiment are given the same reference numerals, and detailed descriptions are omitted.

Referring to FIG. 18, the semiconductor light emitting device 150D according to the fourth embodiment can comprise a light emitting layer 150A, a first electrode 154, a second electrode 155, an insulating layer 157, and a plurality of metal layers 156-1, 156-2 and 156-4. The semiconductor light emitting device 150D according to the fourth embodiment can comprise more components than these.

The plurality of metal layers 156-1, 156-2, and 156-4 can be disposed on the side portion of the light emitting layer 150a. The plurality of metal layers 156-1, 156-2, and 156-4 can be disposed along the perimeter of the side portion of the light emitting layer 150a. For example, the first metal layer 156-1 and the second metal layer 156-2 can be disposed along the perimeter of the side portion of the light emitting layer 150a.

The plurality of metal layers 156-1, 156-2, and 156-4 can comprise a first metal layer 156-1, a second metal layer 156-2, and a fourth metal layer 156-4. Since the first metal layer 156-1 and the second metal layer 156-2 have been previously described, detailed descriptions are omitted.

The fourth metal layer 156-4 can be in contact with the side surface of the light emitting layer 150a. The fourth metal layer 156-4 can be in contact with the side surface of the first conductivity type semiconductor layer 151 of the light emitting layer 150a. The fourth metal layer 156-4 can be disposed between the light emitting layer 150a and the first insulating layer 157-1 of the insulating layer 157.

The fourth metal layer 156-4 can serve to improve electrical characteristics between the metal and semiconductor layer. For example, the fourth metal layer 156-4 can comprise an ohmic layer with excellent ohmic properties. The fourth metal layer 156-4 allows current to flow smoothly from the light emitting layer 150a to the first electrode 154 without loss, thereby improving electrical characteristics. Alternatively, the fourth metal layer 156-4 can comprise a reflective layer, an electrode layer, an adhesive layer, etc.

The upper side of the fourth metal layer 156-4 can be disposed lower than the active layer 152. That is, when the fourth metal layer 156-4 is disposed higher than the active layer 152, an electrical short circuit can occur between the first conductivity type semiconductor layer 151 and the second conductivity type semiconductor layer 153 due to the second metal layer 156-2. Accordingly, the upper side of the fourth metal layer 156-4 can be disposed lower than the active layer 152 such that electrical short circuit can be prevented.

The first metal layer 156-1 and the second metal layer 156-2 can be bent depending on the thickness of the fourth metal layer 156-4. Likewise, the first insulating layer 157-1, the second insulating layer 157-2, and the third insulating layer 157-3 included in the insulating layer 157 can also be bent. According to the embodiment, electrical characteristics can be improved by disposing the fourth metal layer 156-4.

### Display Device

FIG. 19 is a cross-sectional view illustrating a display device according to a first embodiment. FIG. 20 is a cross-sectional view illustrating a backplane substrate according to the first embodiment.

Referring to FIG. 19, the display device 300 according to the first embodiment can comprise a substrate 310, a first assembling wiring 321, a second assembling wiring 322, a first insulating layer 330, and a semiconductor light emitting device 150A, a second insulating layer 350, and an electrode wiring 360. The display device 300 according to the first embodiment can comprise more components than these.

The semiconductor light emitting device can be the semiconductor light emitting device 150A according to the first embodiment, but the semiconductor light emitting devices 150B to 150E according to the second to fifth embodiments can also be equally adopted in the display device 300 according to the first embodiment.

The display device 300 according to the first embodiment can be manufactured using the backplane substrate 300A shown in FIG. 20. That is, the semiconductor light emitting device 150A can be assembled into the assembly hole 340H of the backplane substrate 300A using a self-assembly process. Thereafter, after the barrier rib 340 on the backplane substrate 300A is removed, the second insulating layer 350 and the electrode wiring 360 can be formed through a post-process such that the display device 300 according to the first embodiment can be manufactured. Although the drawing shows the display device 300 with the barrier rib 340 removed, the display device 300 can be provided without the barrier rib 340 being removed. In this instance, the second insulating layer 350 can be omitted.

The backplane substrate 300A can comprise a substrate 310, a first assembling wiring 321, a second assembling wiring 322, a first insulating layer 330, and a barrier rib 340.

The substrate 310 can be a support substrate for supporting the components of the display device 300 according to the first embodiment, that is, the semiconductor light emitting device 150A, the second insulating layer 350, the electrode wiring 360, etc. and can be called a lower substrate or a display substrate. An upper substrate can be disposed on the electrode wiring 360, but is not limited thereto.

The first assembling wiring 321 can be disposed on the substrate 310. The second assembling wiring 322 can be disposed on the substrate 310. For example, the first assembling wiring 321 and the second assembling wiring 322 can be disposed on different layers. For example, the first assembling wiring 321 can be disposed on the lower side of the first insulating layer 330, and the second assembling wiring 322 can be disposed on the upper side of the first insulating layer 330. The first assembling wiring 321 and the second assembling wiring 322 can each serve to assemble the semiconductor light emitting device 150A into the assembly hole 340H using a self-assembly method. That is, the moving semiconductor light emitting device 150A can be assembled in the assembly hole 340H by an assembly device (1100 in FIG. 7) using the DEP force formed by the voltage supplied to the first assembling wiring 321 and the second assembling wiring 322 during self-assembly. The assembly hole 340H can have a diameter greater than the diameter of the semiconductor light emitting device 150A.

The first assembling wiring 321 and the second assembling wiring 322 can each comprise a plurality of metal layers. The first assembling wiring 321 and the second assembling wiring 322 can comprise a main wiring and an auxiliary electrode, respectively. The main wiring of each of the first assembling wiring 321 and the second assembling wiring 322 can be disposed long along one direction of the substrate 310. The auxiliary electrode of each of the first assembling wiring 321 and the second assembling wiring 322 can extend from the main wiring toward the assembly hole 340H. The auxiliary electrode can be electrically connected to the main wiring. The main wiring can be disposed on the auxiliary wiring, and the lower surface of the main wiring can be in contact with the upper surface of the auxiliary wiring, but is not limited thereto.

The first insulating layer 330 can be disposed on the first assembling wiring 321 and the second assembling wiring 322. For example, the first insulating layer 330 can be made of an inorganic material or an organic material. For example, the first insulating layer 330 can be made of a material having a dielectric constant related to DEP force. For example, as the dielectric constant of the first insulating layer 330 increases, the DEP force can increase, but is not limited thereto. The first insulating layer 330 can prevent fluid from directly contacting the first assembling wiring 321 or the second assembling wiring 322 and causing corrosion during self-assembly by the assembly hole 340H of the barrier rib 340 formed later.

The barrier rib 340 can be disposed on the first insulating layer 330. The first insulating layer 330 can have an assembly hole 340H. The assembly hole 340H can be formed in each of the plurality of sub-pixels PX1, PX2, and PX3 of each of the plurality of pixels PX. That is, each sub-pixel PX1, PX2, and PX3 can be formed in one assembly hole 340H, but is not limited thereto. For example, the first insulating layer 330 can be exposed within the assembly hole 340H. For example, the bottom surface 158-2 of the assembly hole 340H can be the upper surface of the first insulating layer 330. The height (or thickness) of the barrier rib 340 can be determined by considering the thickness of the semiconductor light emitting device 150A.

A self-assembly process can be performed on the backplane substrate 300A configured as described above, so that a plurality of semiconductor light emitting devices 150A can be assembled into a plurality of sub-pixels PX1, PX2, and PX3 of each of the plurality of pixels PX on the substrate 310.

As an example, each of a plurality of red semiconductor light emitting devices 150A, a plurality of green semiconductor light emitting devices 150A, and a plurality of blue semiconductor light emitting devices 150A can be sequentially assembled into a plurality of sub-pixels PX1, PX2, and PX3 of each of the plurality of pixels PX on the substrate 310.

As another example, a plurality of red semiconductor light emitting devices, a plurality of green semiconductor light emitting devices, and a plurality of blue semiconductor light emitting devices can be simultaneously assembled in a plurality of sub-pixels PX1, PX2, and PX3 of each of the plurality of pixels PX on the substrate 310. A plurality of red semiconductor light emitting devices, a plurality of green semiconductor light emitting devices, and a plurality of blue semiconductor light emitting devices can be dropped into the fluid of the chamber and mixed. Subsequently, the same self-assembly process is performed so that a plurality of red semiconductor light emitting devices, a plurality of green semiconductor light emitting devices, and a plurality of blue semiconductor light emitting devices can be simultaneously assembled in a plurality of sub-pixels PX1, PX2, and PX3 of each of the plurality of pixels PX on the substrate 310.

For simultaneous self-assembly, the red semiconductor light emitting device, the green semiconductor light emitting device, and the blue semiconductor light emitting device can each have exclusivity from each other. That is, the shapes and sizes of the red semiconductor light emitting device, green semiconductor light emitting device, and blue semiconductor light emitting device can be different. For example, the red semiconductor light emitting device can have a circular shape, the green semiconductor light emitting device can have a first oval shape with a first minor axis and a first major axis, and the blue semiconductor light emitting device can have a second oval shape. The second oval can have a second minor axis that is smaller than the first minor axis and a second major axis that is greater than the first major axis.

After the semiconductor light emitting device is assembled, a fixing member can be disposed between the semiconductor light emitting device and the first insulating layer 330 within the assembly hole 340H, so that the semiconductor light emitting device can be fixed to the first insulating layer 330 by a fixing member. The fixing member can comprise an organic material such as PAC or a photosensitive material, but is not limited thereto.

Thereafter, a thermal compression process can be performed so that the first electrode 154 of the semiconductor light emitting device 150A can be electrically connected to the second assembling wiring 322. The electrode layer 154-2 of the first electrode 154 can comprise solder metal. The electrode layer 154-2 of the first electrode 154 can be melted and cooled through a thermal compression process, so that the first electrode 154 of the semiconductor light emitting device 150A can be physically and electrically connected to the second assembling wiring 322.

Afterwards, an etching process can be performed to remove the barrier rib 340. Thereafter, electrical connection can be made to the semiconductor light emitting device 150A using a post-process. That is, the second insulating layer 350 and the electrode wiring 360 can be formed using a post-process.

The second insulating layer 350 can be disposed on the first insulating layer 330. The second insulating layer 350 can be disposed on the semiconductor light emitting device 150A as well as the first insulating layer 330. In addition, the second insulating layer 350 can be disposed along the perimeter of the side portion of the semiconductor light emitting device 150A. The semiconductor light emitting device 150A can be firmly fixed by the second insulating layer 350.

the second insulating layer 350 may not be disposed on the upper side of the semiconductor light emitting device 150A. The second insulating layer 350 can be a planarization layer to easily form the electrode wiring 360 or other layers. Accordingly, the upper surface of the second insulating layer 350 can have a straight plane, but is not limited thereto. The first insulating layer 330 and the second insulating layer 350 can each comprise an organic material or an inorganic material. For example, the first insulating layer 330 can comprise an inorganic material, and the second insulating layer 350 can comprise an organic material.

The electrode wiring 360 can be disposed on the second insulating layer 350. The electrode wiring 360 can extend on the second insulating layer 350 and be electrically connected to the upper side of the semiconductor light emitting device 150A, that is, the second electrode 155. The upper surface of the second electrode 155 of the semiconductor light emitting device 150A and the upper surface of the second insulating layer 350 can be positioned on the same horizontal line. In this instance, the electrode wiring 360 can be deposited and patterned on the substrate 310, so that the electrode wiring 360 can have a straight pattern and can be disposed on the second insulating layer 350 and the second electrode 155 of the semiconductor light emitting device 150A.

By completing this electrical connection, the semiconductor light emitting device 150A can emit light by the voltage (or current) supplied to the electrode wiring 360, the first assembling wiring 321, and/or the second assembling wiring 322.

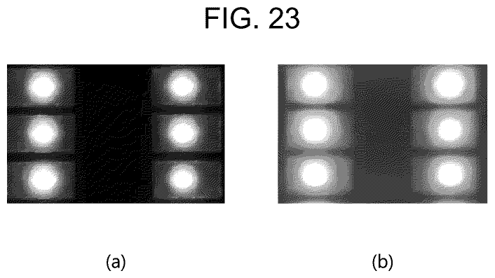

FIG. 23 shows the luminance of a semiconductor light emitting device in a display device according to a comparative example and the embodiment. The comparative example is a case in which a reflective layer is not disposed around the light emitting layer 150a, and the embodiment is a case in which a reflective layer is disposed around the light emitting layer 150a. It can be seen that much higher luminance is obtained in the embodiment (FIG. 23b) compared to the comparative example (FIG. 23a).

FIG. 21 is a cross-sectional view illustrating a display device according to a second embodiment. FIG. 22 is a cross-sectional view illustrating a backplane substrate according to the second embodiment. The second embodiment is the same as the first embodiment except for the side connection of the semiconductor light emitting device 150A. In the second embodiment, components having the same structure, shape and/or function as those of the first embodiment are given the same reference numerals, and detailed description is omitted.

Referring to FIG. 21, the display device 301 according to the second embodiment can comprise a substrate 310, a first assembling wiring 321, a second assembling wiring 322, a first insulating layer 330, and a semiconductor light emitting device 150A, a connection electrode 370, a second insulating layer 350, and an electrode wiring 360. The display device 301 according to the second embodiment can comprise more components than these.

The semiconductor light emitting device can be the semiconductor light emitting device 150A according to the first embodiment, but the semiconductor light emitting devices 150B to 150E according to the second to fifth embodiments can also be equally adopted in the display device 301 according to the second embodiment.

The display device 301 according to the second embodiment can be manufactured using the backplane substrate 301A shown in FIG. 22. That is, the semiconductor light emitting device 150A can be assembled into the assembly hole 340H of the backplane substrate 301A using a self-assembly process. Thereafter, after the barrier rib 340 on the backplane substrate 301A is removed, the connection electrode 370, the second insulating layer 350, and the electrode wiring 360 can be formed through a post-process such that the display device 301 according to the second embodiment can be manufactured.

The connection electrode 370 can be formed along the perimeter of the semiconductor light emitting device 150A. Since the barrier rib 340 is removed and the spatial margin for forming the connection electrode 370 increases, the connection electrode 370 can be easily formed without electrical disconnection.

The connection electrode 370 can electrically connect the semiconductor light emitting device 150A to the first assembling wiring 321 and/or the second assembling wiring 322.

The insulating layer 157 of the semiconductor light emitting device 150A, that is, the lower side of the third insulating layer 157-3, can be removed to expose the second metal layer 156-2. Thereafter, the first insulating layer 330 can be removed along the perimeter of the semiconductor light emitting device 150A within the assembly hole 340H, so that the first assembling wiring 321 and/or the second assembling wiring 322 can be exposed to the outside. Thereafter, the connection electrode 370 can be formed along the perimeter of the semiconductor light emitting device 150A, so that the first electrode 154 of the semiconductor light emitting device 150A can be connected to the first assembling wiring 321 and/or the second assembling wiring 322 by the connection electrode 370. For example, since the connection electrode 370 is electrically connected to the second metal layer 156-2 and the first electrode 154, the electrical area of the connection electrode 370 can be increased. Accordingly, the electrical characteristics or optical characteristics of the semiconductor light emitting device 150A can be improved. That is, it can be driven in a low voltage, and luminous efficiency and optical brightness can be improved.

The connection electrode 370 can be formed using electroplating or sputtering methods. The aforementioned display devices can be display panels. That is, in the embodiments, the display device and the display panel can be understood as the same meaning. In the embodiments, the display device in a practical sense can comprise a display panel and a controller (or processor) capable of controlling the display panel to display an image.

The embodiment can be adopted in the display field for displaying images or information. The embodiment can be adopted in the display field for displaying images or information using a semiconductor light emitting device. The semiconductor light emitting device can be a micro-level semiconductor light emitting device or a nano-level semiconductor light emitting device.

For example, the embodiment can be adopted for TV, signage, mobile terminal such as handheld phone and smart phone, display for computer such as laptop and desktop, head-up display (HUD) for automobiles, backlight unit for display, XR (Extend Reality) such as AR, VR, MR (mixed reality), etc.

Various embodiments described herein may be implemented in a computer-readable medium using, for example, software, hardware, or some combination thereof. For example, the embodiments described herein may be implemented within one or more of Application Specific Integrated Circuits (ASICs), Digital Signal Processors (DSPs), Digital Signal Processing Devices (DSPDs), Programmable Logic Devices (PLDs), Field Programmable Gate Arrays (FPGAs), processors, controllers, micro-controllers, microprocessors, other electronic units designed to perform the functions described herein, or a selective combination thereof. In some cases, such embodiments are implemented by the controller. That is, the controller is a hardware-embedded processor executing the appropriate algorithms (e.g., flowcharts) for performing the described functions and thus has sufficient structure. Also, the embodiments such as procedures and functions may be implemented together with separate software modules each of which performs at least one of functions and operations. The software codes can be implemented with a software application written in any suitable programming language. Also, the software codes can be stored in the memory and executed by the controller, thus making the controller a type of special purpose controller specifically configured to carry out the described functions and algorithms. Thus, the components shown in the drawings have sufficient structure to implement the appropriate algorithms for performing the described functions.

The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

What is claimed is:

1. A semiconductor light emitting device, comprising:
a light emitting layer;
a first electrode on a lower side of the light emitting layer;
a second electrode on an upper side of the light emitting layer;
an insulating layer on a side portion of the light emitting layer and overlapping at least a portion of the first electrode and overlapping at least a portion of the second electrode; and
a plurality of metal layers spaced apart from each other in the insulating layer, the plurality of metal layers including:
a first metal layer including a reflective layer; and
a second metal layer including a magnetic layer.

2. The semiconductor light emitting device of claim 1, wherein the light emitting layer comprises:
a first conductivity type semiconductor layer;
an active layer on the first conductivity type semiconductor layer; and
a second conductivity type semiconductor layer on the active layer.

3. The semiconductor light emitting device of claim 2,
wherein the second metal layer is spaced outwardly from the first metal layer.

4. The semiconductor light emitting device of claim 3, wherein the insulating layer comprises:
a first insulating layer between the light emitting layer and the first metal layer;
a second insulating layer between the first metal layer and the second metal layer; and
a third insulating layer on an outer side surface of the second metal layer.

5. The semiconductor light emitting device of claim 4, wherein the plurality of metal layers further includes:
a third metal layer spaced outwardly from the second metal layer.

6. The semiconductor light emitting device of claim 5, wherein
the third metal layer includes a reflective layer.

7. The semiconductor light emitting device of claim 5, wherein an upper side of at least one or more of the first metal layer, the second metal layer, and the third metal layer coincides with an upper surface of the second electrode.

8. The semiconductor light emitting device of claim 5, wherein an upper side of at least one or more of the first metal layer, the second metal layer, and the third metal layer is located higher than an upper surface of the second conductivity type semiconductor layer.

9. The semiconductor light emitting device of claim 5, wherein an upper side of at least one or more of the first metal layer, the second metal layer, and the third metal layer is in contact with the third insulating layer.

10. The semiconductor light emitting device of claim 5, wherein the insulating layer further includes:
a fourth insulating layer between the second metal layer and the third metal layer.

11. The semiconductor light emitting device of claim 10, wherein an upper side of at least one or more of the first insulating layer, the second insulating layer, and the fourth insulating layer is in contact with the third insulating layer.

12. The semiconductor light emitting device of claim 10, wherein an edge area of the first electrode is spaced apart from the first metal layer, the second metal layer, and the third metal layer, and
wherein a space is formed between lower sides of at least two or more of the first insulating layer, the second insulating layer, the third insulating layer, and the fourth insulating layer.

13. The semiconductor light emitting device of claim 4, wherein an edge area of the first electrode is spaced apart from the first metal layer with the first insulating layer therebetween.

14. The semiconductor light emitting device of claim 5, wherein the plurality of metal layers further includes:
a fourth metal layer spaced inwardly from the first metal layer.

15. The semiconductor light emitting device of claim 14, wherein the fourth metal layer is disposed between the light emitting layer and the first insulating layer.

16. The semiconductor light emitting device of claim 14, wherein the fourth metal layer comprises an ohmic layer.

17. The semiconductor light emitting device of claim 14, wherein an upper side of the fourth metal layer is located lower than the active layer.

18. The semiconductor light emitting device of claim 14, wherein an edge area of the first electrode is electrically connected to at least one or more of the first metal layer, the second metal layer, the third metal layer, and the fourth metal layer.

19. The semiconductor light emitting device of claim 1, wherein each of the plurality of metal layers has a cylindrical structure.

20. A display device, comprising:
a substrate comprising a plurality of sub-pixels constituting a pixel; and
a plurality of semiconductor light emitting devices in the plurality of sub-pixels, each semiconductor light emitting device including:
a light emitting layer;
a first electrode on a lower side of the light emitting layer;
a second electrode on an upper side of the light emitting layer;
an insulating layer on a side portion of the light emitting layer, the insulating layer overlapping at least a portion of the first electrode and overlapping at least a portion of the second electrode; and
a plurality of metal layers spaced apart from each other in the insulating layer, the plurality of metal layers including:
a first metal layer including a reflective layer;
a second metal layer including a magnetic layer; and
a third metal layer including a reflective layer.

21. The display device of claim 20, wherein the insulating layer includes:
a first insulating layer between the light emitting layer and the first metal layer;
a second insulating layer between the first metal layer and the second metal layer; and
a third insulating layer on an outer side surface of the second metal layer.

22. The display device of claim 21, wherein the insulating layer includes:
a first insulating layer between the light emitting layer and the first metal layer;
a second insulating layer between the first metal layer and the second metal layer; and
a third insulating layer on an outer side surface of the second metal layer.

23. A method of mounting semiconducting light emitting devices onto a substrate, comprising:
disposing a plurality of semiconducting light emitting devices into a chamber filled with a fluid;
disposing a substrate over the chamber, the substrate including a plurality of assembly holes corresponding to the plurality of semiconducting light emitting devices;
moving the plurality of semiconducting light emitting devices to the plurality of assembly holes by generating a magnetic field or by generating an electric field.
